(19) United States
(12) Patent Application Publication
(10) Pub. No.: US 2026/0164719 A1
(43) Pub. Date: Jun. 11, 2026

(54) SEMICONDUCTOR STRUCTURE INCLUDING DIELECTRIC WALL AND METHOD FOR MANUFACTURING THE SAME

(71) Applicant: Taiwan Semiconductor Manufacturing Company, Ltd., Hsinchu (TW)

(72) Inventors: I-Han HUANG, Hsinchu (TW); Chu-Yuan HSU, Hsinchu (TW); Jia-Chuan YOU, Hsinchu (TW); Chia-Hao CHANG, Hsinchu (TW); Kuo-Cheng CHIANG, Hsinchu (TW)

(73) Assignee: Taiwan Semiconductor Manufacturing Company, Ltd., Hsinchu (TW)

(21) Appl. No.: 18/976,549

(22) Filed: Dec. 11, 2024

(51) Int. Cl. H10D 30/67; H01L 21/3213; H01L 21/762; H10D 30/00; H10D 30/01; H10D 62/10

(52) U.S. Cl. CPC H10D 30/6736; H10D 30/6735; H10P 50/00; H10W 10/014; H10W 10/17; H10D 30/0191; H10D 30/502; H10D 30/6757; H10D 62/121

(57) ABSTRACT

A method for manufacturing a semiconductor structure includes: forming a patterned structure which includes a first protrusion, a second protrusion, a first channel portion, a second channel portion, a gate electrode surrounding the first and second channel portions, and a gate dielectric disposed to separate the gate electrode from the first and second channel portions; performing a first etching process to form an upper trench in an upper portion of the gate electrode; performing a second etching process on a lower portion of the gate electrode through the upper trench, so that the gate electrode is formed into two gate parts which are separated from each other by the upper trench and a lower trench that extends downwardly from the upper trench; performing a third etching process on the two gate parts to widen the lower trench; and forming a dielectric wall in the upper trench and the lower trench.

### BACKGROUND

Nowadays, integrated circuits (ICs) are widely used in consumer electronics products and automotive electronics products. Transistors are key active components in modern ICs. In order to integrate a large number of transistors per unit area for supporting increasing complexity and sophisticated functions of the electronic products, the dimension of the ICs are continuously being made smaller. In addition, various approaches are being continuously developed for optimizing parameters of the transistors in the ICs, so as to manufacture electronics products with relatively low power consumption, long service lifetime and high computing speed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing a semiconductor structure in accordance with some embodiments.

FIGS. 2 to 15 illustrate schematic views of intermediate stages of the method depicted in FIG. 1 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects±20%, in some aspects±10%, in some aspects±5%, in some aspects±2.5%, in some aspects±1%, in some aspects±0.5%, and in some aspects±0.1% from the specified amount, as such variations are appropriate to perform the disclosed methods or employ the disclosed compositions and could be understood by those skilled in the art after reviewing the present disclosure.

The term “source/drain portion(s)” may refer to a source or a drain, individually or collectively dependent upon the context.

The present disclosure is directed to a method for forming a dielectric wall in a semiconductor structure, and the semiconductor structure manufactured thereby. In some embodiments, the semiconductor structure including the dielectric wall may be referred to as a forksheet structure. The forksheet structure is an advanced variation of a gate-all-around structure (GAA) in advanced technology nodes of semiconductor fabrication. The dielectric wall in the forksheet structure is formed between an n-channel MOSFET (NMOS) and a p-channel MOSFET (PMOS), so that a spacing between the NMOS and the PMOS (i.e., OD-to-OD spacing) can be effectively reduced. In this disclosure, the dielectric wall is formed after a replacement gate process and a dipole engineering process for threshold voltage adjustment. During the replacement gate process and the dipole engineering process, sacrificial material(s) and/or dipole material(s) among the channels may be effectively removed by etchant(s) without interference from the dielectric wall. Therefore, undesired residues remaining among the channels, which resulted from incomplete removal of the sacrificial material(s) and/or the dipole material(s), can be prevented.

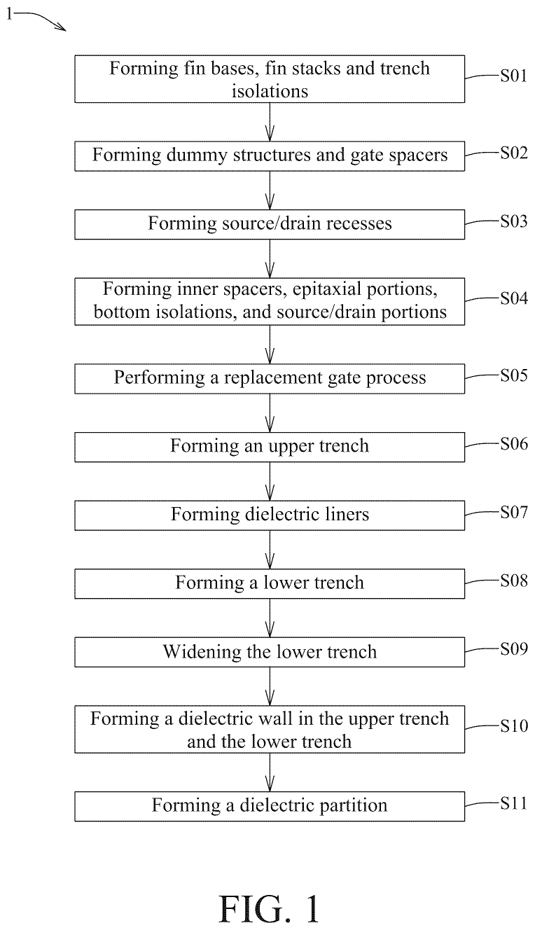

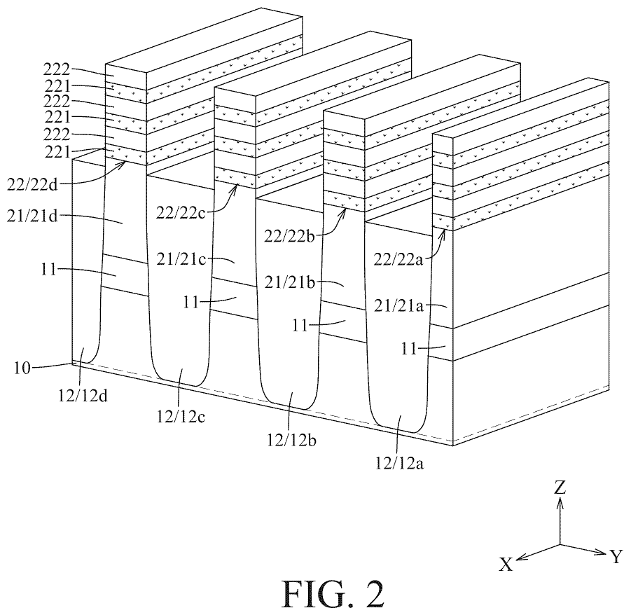

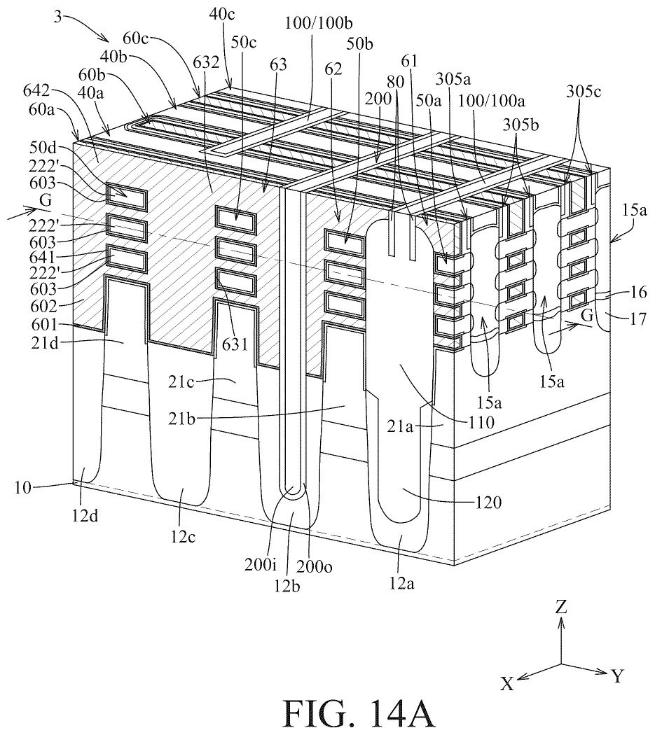

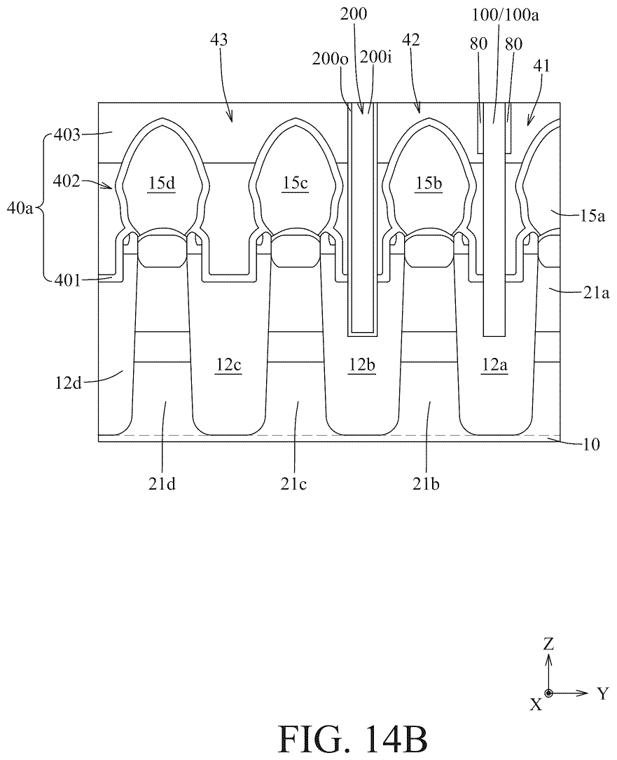

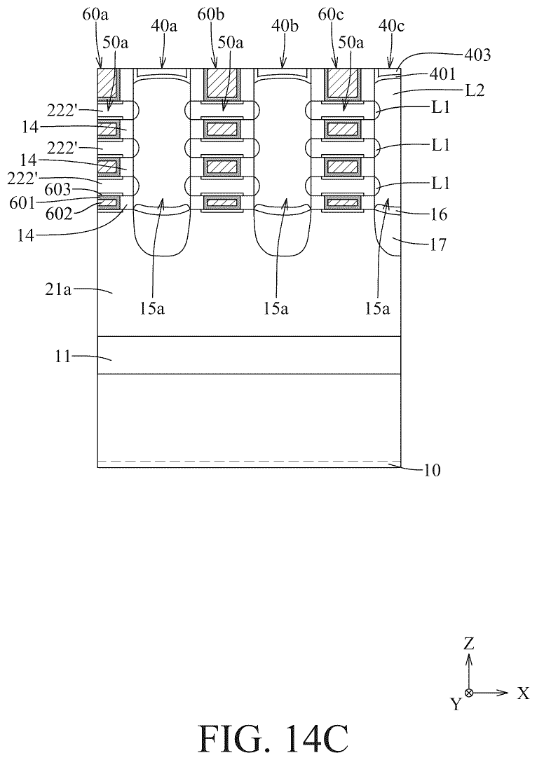

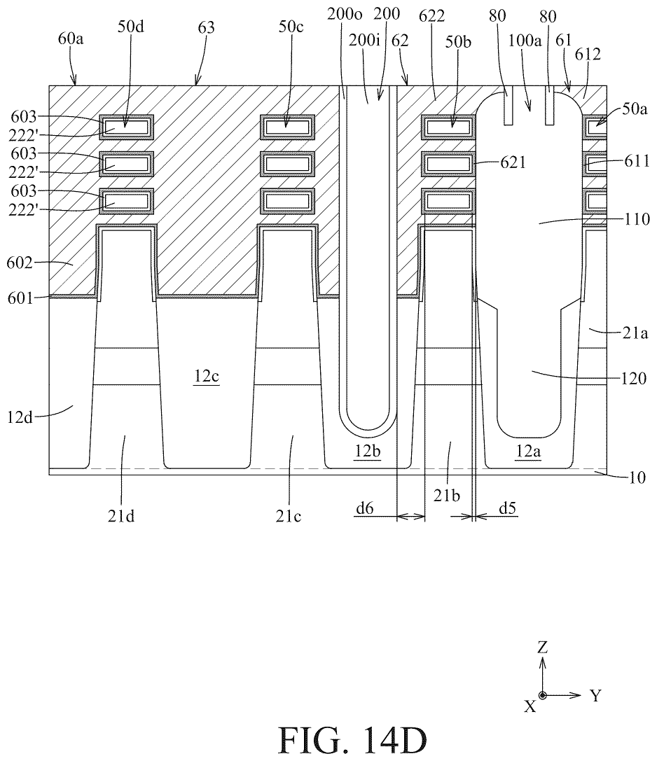

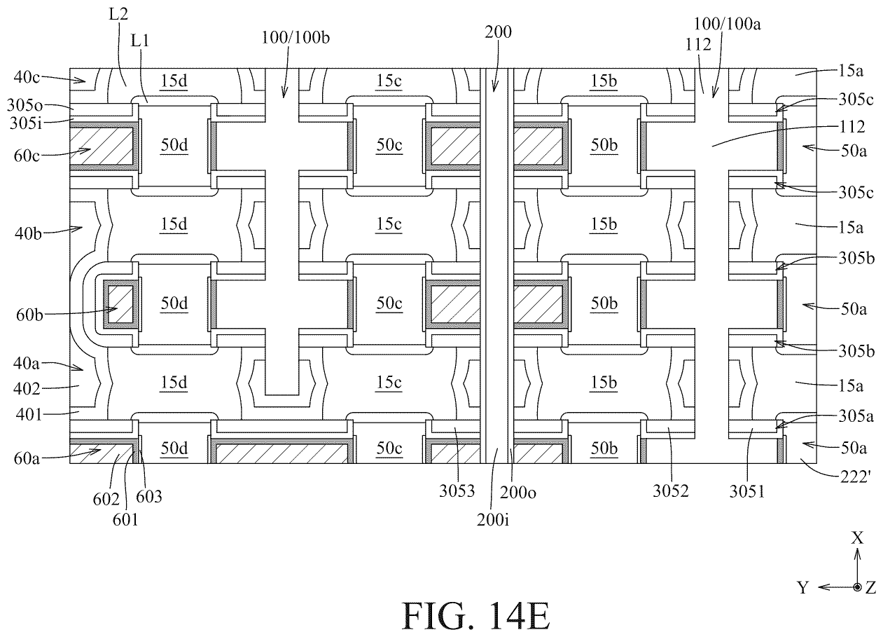

FIG. 1 is a flow diagram illustrating a method 1 for manufacturing a semiconductor structure (for example, but not limited to, a semiconductor structure 3 shown in FIG. 14A) in accordance with some embodiments. The method 1 may include steps S01 to S11. FIGS. 2 to 15 illustrate schematic views of intermediate stages of the method 1 in accordance with some embodiments. Some repeating structures are omitted in FIGS. 2 to 15 for the sake of brevity.

Referring to FIG. 1 and the example illustrated in FIG. 2, the method 1 begins at step S01, where fin bases 21 (including the fin bases 21a, 21b, 21c, 21d) are formed on a substrate 10, fin stacks 22 (including the fin stacks 22a, 22b, 22c, 22d) respectively formed on the fin bases 21, and then trench isolations 12 (including the trench isolations 12a, 12b, 12c, 12d) are formed on the substrate 10 to alternate with the fin bases 21. In some embodiments, the fin bases 21 each may be also referred to as a protrusion on the substrate 10. The number of the fin bases 21 may vary according to practical applications and is not limited the number exemplarily shown in FIG. 2.

In some embodiments, the substrate 10 may include elemental semiconductor materials (such as crystalline silicon, diamond, or germanium), compound semiconductor materials (such as silicon carbide, gallium arsenide, indium arsenide, or indium phosphide), alloy semiconductor materials (such as silicon germanium, silicon germanium carbide, gallium arsenide phosphide, or gallium indium phosphide), or combinations thereof. In some embodiments, the substrate 10 may be a bulk semiconductor substrate, for example, but not limited to, a bulk substrate of silicon, germanium, silicon germanium, or other suitable semiconductor materials (such as the examples described earlier in the same paragraph). In some embodiments, the substrate 10 may be formed with an n-type well having an n-type conductivity and a p-type well having a p-type conductivity. Each of the n-type well and the p-type well may be formed by introducing an n-type impurity or a p-type impurity into the substrate 10 by an implantation processes. In some embodiments, the n-type impurity may include phosphorous (P, ³¹P), arsenic (As), antimony (Sb), or combinations thereof. In some embodiments, the p-type impurities may include boron or boron compound (for example, B, ¹¹B, BF₂), aluminum (Al), indium (In), gallium (Ga), or combinations thereof. In some other embodiments not shown herein, the substrate 10 may be configured as a semiconductor-on-insulator substrate. Other suitable materials and configurations for the substrate 10 are within the contemplated scope of the present disclosure.

Each of the fin bases 21 is elongated in an X direction. The fin bases 21 protrude from a front surface of the substrate 10 and are disposed to alternate with the trench isolations 12 in a Y direction transverse to the X direction. Each of the fin bases 21 includes or is made of a semiconductor material (such as the examples of the semiconductor material suitable for the substrate 10 as described in the previous paragraph). In some embodiments, each of the fin bases 21 may be independently implanted with a p-type impurity to serve as a p-type well, or may be implanted with an n-type impurity to serve as an n-type well. The examples of the p-type impurity and the n-type impurity are similar to those as described in the previous paragraph. In some embodiments, an etch stop layer 11 is formed in each of the fin bases 21, and serves as an etch stop point during a backside process which is performed from a back surface of the substrate 10. The front surface and the back surface of the substrate 10 are opposite to each other. In some embodiments, the etch stop layer 11 is spaced apart from the substrate 10 and a respective one of the fin stacks 22. The etch stop layer 11 includes a material that is different from the fin bases 11. In some embodiments, the etch stop layer 11 includes or is made of silicon oxide, silicon nitride, silicon oxynitride, silicon oxycarbide, silicon carbon nitride, silicon oxycarbon nitride, silicon germanium with germanium in an atomic percentage ranging from about 10% to about 50%, other suitable materials, or combinations thereof. In some embodiments, the etch stop layer 11 may have a thickness ranging from about 5 nm to about 30 nm.

Each of the fin stacks 22 is elongated in the X direction. Each of the fin stacks 22 includes first layers 221 and second layers 222 disposed to alternate with the first layers 221 in a Z direction transverse the X and Y direction. In some embodiments, the X, Y and Z directions are perpendicular to each other. In some embodiments, an uppermost one of the second layers 222 is disposed over an uppermost one of the first layers 221 opposite to the substrate 10. In some embodiments, a lowermost one of the second layers 222 is spaced apart from a respective one of the fin bases 21 via a lowermost one of the first layers 221. Each of the first layers 221 is made of a first semiconductor material, and each of the second layers 222 is made of a second semiconductor material that is different from the first semiconductor material, so that the first layers 221 may be selectively removed, and the second layers 222 are substantially intact due to different etching selectivity ratios. Possible semiconductor materials suitable for the first and second layers 221, 222 are similar to those for the substrate 10, and thus the details thereof are omitted for the sake of brevity. In some embodiments, the first layers 221 are made of silicon germanium, and the second layers 222 are made of silicon. Other materials suitable for the first and second layers 221, 222 are within the contemplated scope of the present disclosure.

In some embodiments, formation of the fin bases 21 and the fin stacks 22 may include (i) forming a lamination structure (not shown) on a starting substrate (not shown) by chemical vapor deposition (CVD), atomic layer deposition (ALD), an epitaxial growth process (such as molecular-beam epitaxy (MBE), selective area epitaxy (SAE), etc.), or other suitable deposition techniques, and (ii) patterning the lamination structure and the starting substrate using a photolithography process followed by an etching process. As a result, the lamination structure is patterned into the fin stacks 22 each having a predetermined dimension in the Y direction, and the starting substrate is patterned into the substrate 10 and the fin bases 21.

In some embodiments, the trench isolations 12 may each be a shallow trench isolation (STI), a deep trench isolation (DTI), or other suitable structures. In some embodiments, the trench isolations 12 may include silicon oxide, silicon nitride, silicon oxynitride, silicon oxide formed from tetraethoxysilane (TEOS), other low-k dielectric materials, or combinations thereof. Other insulating materials suitable for the trench isolations 12 are within the contemplated scope of the present disclosure.

In some embodiments, formation of the trench isolations 12 may include (i) forming an isolation layer over the substrate 10, the fin bases 21 and the fin stacks 22 followed by a planarization process, for example, but not limited to, chemical mechanism polishing (CMP), to form isolation regions (not shown), and (ii) recessing the isolation regions until an upper part of each of the fin bases 21 is exposed.

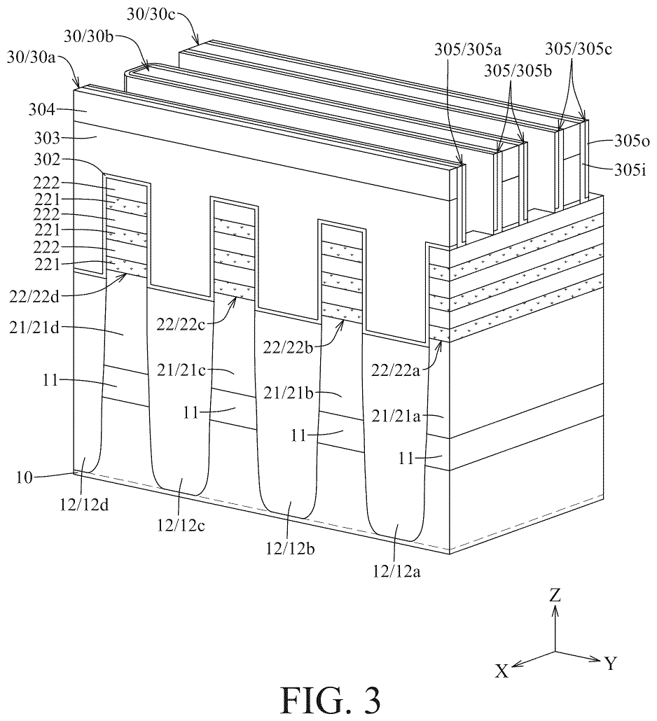

Referring to FIG. 1 and the example illustrated in FIG. 3, the method 1 proceeds to step S02, where dummy structures 30 (including the dummy structures 30a, 30b, 30c) and pairs of gate spacers 305 (including the gate spacers 305a, 305b, 305c) are formed. FIG. 3 is a schematic perspective view similar to that of FIG. 2, but illustrating the structure after step S02. The number of the dummy structures 30 may vary according to practical applications and is not limited the number exemplarily shown in FIG. 2.

Each of the dummy structures 30 and the gate spacers 305 is elongated in the Y direction and is formed over the fin stacks 22 and the trench isolations 12. The dummy structures 30 are spaced apart from each other in the X direction. Each pair of the gate spacers 305 are respectively disposed at two opposite sides of a respective one of the dummy structures 30 in the X direction. Each of the fin stacks 22 has exposed portions which are exposed from the dummy structures 30 and the gate spacers 305.

Each of the dummy structures 30 includes a dummy dielectric 302 disposed over the fin stacks 22 and the trench isolations 12, a dummy gate 303 disposed on the dummy dielectric 302, and a hard mask 304 disposed on the dummy gate 303. In some embodiments, the dummy dielectric 302 may include silicon oxide, silicon nitride, silicon oxynitride, high dielectric constant (k) materials, other suitable dielectric materials, or combinations thereof. In some embodiments, the dummy gate 303 may include polycrystalline silicon, single crystalline silicon, amorphous silicon, or combinations thereof. In some embodiments, the hard mask 304 may include silicon nitride, silicon oxide, silicon oxynitride, or combinations thereof. Other materials suitable for the dummy structures 30 are within the contemplated scope of the present disclosure. In some embodiments, formation of the dummy structures 30 may include (i) sequentially forming a first dummy layer (not shown) for forming the dummy dielectric 302 and a second dummy layer (not shown) for forming the dummy gate 303 over the fin stacks 22 and the trench isolations 12 by CVD, ALD, physical vapor deposition (PVD), or other suitable deposition techniques, (ii) performing a planarization process (e.g., CMP) to obtain a planar upper surface of the second dummy layer, (iii) forming a third dummy layer (not shown) for forming the hard mask 304 on the planarized second dummy layer, and (iv) patterning the first dummy layer, the planarized second dummy layer and the third dummy layer using a photolithography process followed by an etching process, thereby obtaining the dummy structures 30.

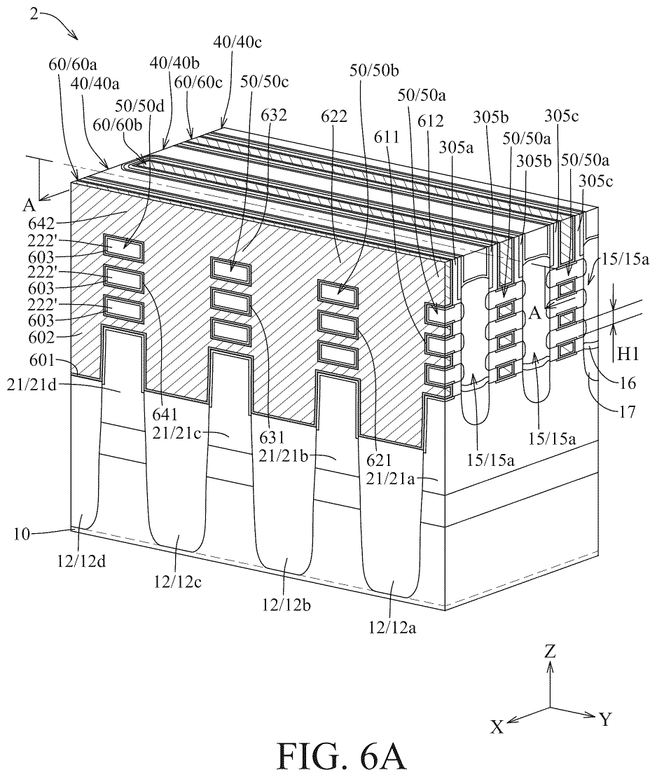

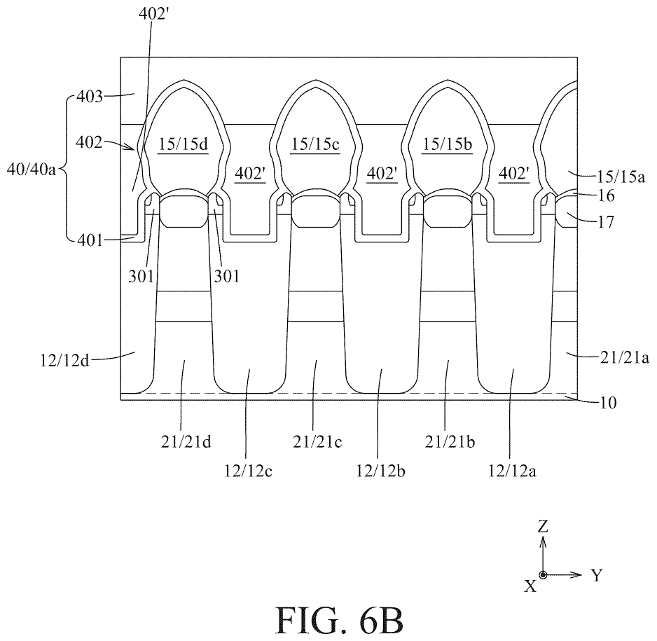

In some embodiments, each of the gate spacers 305 includes or is made of, for example, but not limited to, silicon oxide, silicon nitride, carbon-doped silicon oxide (which may be referred to as silicon oxycarbide), nitride-doped silicon oxide (which may be referred to as silicon oxynitride), silicon oxycarbon nitride, silicon carbon nitride, a porous oxide material, other suitable low dielectric constant (low-k) materials, or combinations thereof. In some embodiments, a thickness of each of the gate spacers 305 in the X direction may range from about 2 nm to about 6 nm. In some embodiments, each of the gate spacers 305 may be configured as a single layer structure or a multi-layered structure. For example, as shown in FIG. 6A, each of the gate spacers 305 is formed as a bi-layered structure including an outer sub-layer 3050 and an inner sub-layer 305i which is disposed between the outer sub-layer 3050 and a corresponding one of the dummy structures 30. The outer sub-layer 3050 has a dielectric constant value (k value) that is greater than a k value of the inner sub-layer 305i. The k value of each of the outer and inner sub-layers 3050, 305i may be adjusted by varying the proportions of silicon, oxygen, carbon, nitrogen, and/or other elements (such as hydrogen) in the dielectric material thereof.

In some embodiments, formation of the gate spacers 305 includes forming a spacer layer (not shown) to cover the dummy structures 30, the exposed portions of the fin stacks 22 and the trench isolations 12 by CVD, ALD, PVD, or other suitable deposition techniques, and performing an anisotropic etching process on the spacer layer to remove horizontal portions of the spacer layer, while leaving vertical portions of the spacer layer. The vertical portions of the spacer layer remain at side surfaces of the gate structures 30 serve as the gate spacers 305, and the vertical portions of the spacer layer remain at side surfaces of the exposed portions of each of the fin stacks 22 serve as pairs of fin spacers 301 (shown in FIG. 6B). Each pair of the fin spacers 301 are respectively formed on two corresponding adjacent ones of the trench isolations 12 and respectively located at two opposite sides of a respective one of the exposed portions of each of the fin stacks 22 in the Y direction.

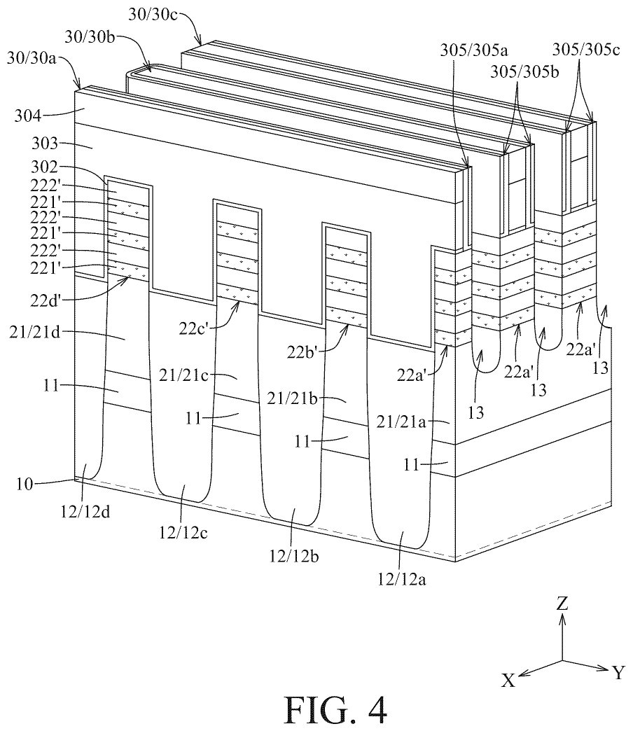

Referring to FIG. 1 and the example illustrated in FIG. 4, the method 1 proceeds to step S03, where the exposed portions of each of the fin stacks 22 (see FIG. 3) are etched to form source/drain recesses 13, respectively, by an etching technique (for example, but not limited to, dry etching, wet etching, or a combination thereof). FIG. 4 is a schematic perspective view similar to that of FIG. 3, but illustrating the structure after step S03.

In step S03, the fin stack 22a is formed into three stacking portions 22a′ spaced apart from each other in the X direction, the fin stack 22b is formed into three stacking portions 22b′ (only one of which can be seen in FIG. 4) spaced apart from each other in the X direction, the fin stack 22c is formed into three stacking portions 22c′ (only one of which can be seen in FIG. 4) spaced apart from each other in the X direction, and the fin stack 22d is formed into three stacking portions 22d′ spaced apart from each other in the X direction. Each of the stacking portions 22a′, 22b′, 22c′, 22d′ is located beneath a corresponding one of the dummy structures 30a, 30b, 30c. Each of the stacking portions 22a′, 22b′, 22c′, 22d′ includes first films 221′ which are respectively formed from the first layers 221, and second films 222′ which are respectively formed from the second layers 222. Each of the fin bases 21a, 21b, 21c, 21d is partially exposed from corresponding ones of the source/drain recesses 13. In some embodiments, the fin bases 21a, 21b, 21c, 21d are etched such that each of the source/drain recesses 13 may extend into a corresponding one of the fin bases 21a, 21b, 21c, 21d by a predetermined depth.

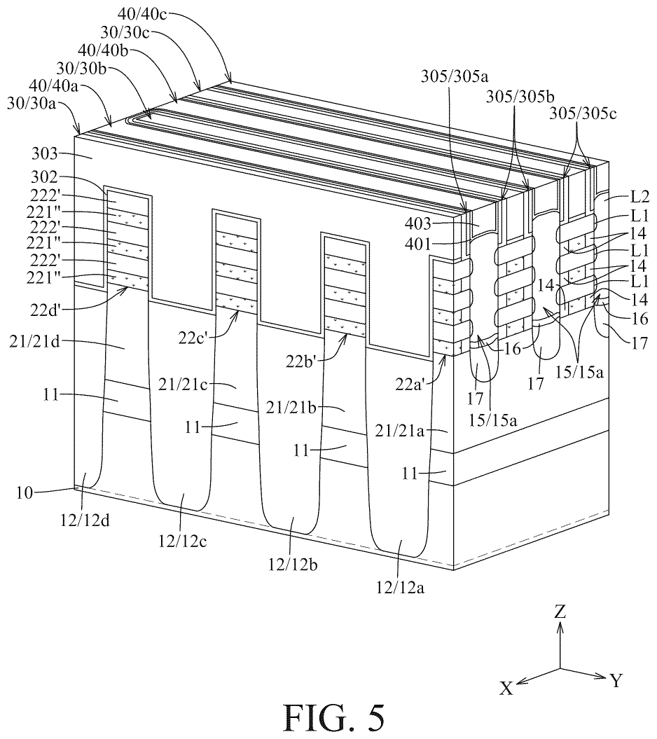

Referring to FIG. 1 and the example illustrated in FIG. 5, the method 1 proceeds to step S04, where inner spacers 14, epitaxial portions 17, bottom isolations 16, source/drain portions 15 (including the source/drain portions 15a, 15b, 15c, 15d, see also FIG. 14E) and isolation portions 40 (including the isolation portions 40a, 40b, 40c) are formed. FIG. 5 is a schematic perspective view similar to that of FIG. 4, but illustrating the structure after step S04.

In some embodiments, step S04 may include multiple sub-steps in the following.

Before step S04, each of the first films 221′ in the stacking portions 22a′, 22b′, 22c′, 22d′ (see FIG. 4) has two end portions respectively exposed from two corresponding adjacent ones of the source/drain recesses 13. In step S04, firstly, the end portions of the first films 221′ are etched by an etching process to form grooves (not shown), respectively, while keeping the second films 222′ substantially intact. The etched first films are denoted by 221″. Then, the inner spacers 14 are respectively formed in the grooves by depositing a low-k dielectric material of the inner spacers 14 to cover each of the etched first films 221″ and fill the grooves by CVD, ALD, PVD, or other suitable deposition techniques, and then removing excess portions of the low-k dielectric material by an anisotropic etching process, thereby obtaining the inner spacers 14. Each pair of the inner spacers 14 are respectively formed at two opposite sides of a respective one of the etched first films 221″. In some embodiments, the inner spacers 14 may include silicon oxide, silicon oxycarbide, silicon oxynitride, silicon oxycarbide, silicon oxycarbonitride, air gap, other suitable low-k dielectric materials, or combinations thereof. In some embodiments, a thickness of each of the inner spacers 14 in the X direction may range from about 2 nm to about 8 nm.

After formation of the inner spacers 14, the epitaxial portions 17, the bottom isolations 16, and the source/drain portions 15 are sequentially formed in the source/drain recesses 13 (see FIG. 4). Each of the second films 222′ in the stacking portions 22a′, 22b′, 22c′, 22d′ (see FIG. 4) is prevented from being covered by a corresponding adjacent one of the epitaxial portions 17 and a corresponding adjacent one of the bottom isolations 16. As such, each of the second films 222′ in the stacking portions 22a′, 22b′, 22c′, 22d′ is connected to two corresponding adjacent ones of the source/drain portions 15.

In some embodiments, each of the epitaxial portions 17 includes a semiconductor material (such as the examples of the semiconductor material for forming the substrate 10). In some embodiments, each of the epitaxial portions 17 is independently made of non-doped silicon, silicon germanium, or boron-doped silicon. In some embodiments, a depth of each of the epitaxial portions 17 in the Z direction ranges from about 5 nm to about 45 nm. In some embodiments, each of the epitaxial portions 17 is formed by an epitaxial growth process (such as molecular-beam epitaxy (MBE), selective area epitaxy (SAE), etc.), or other suitable deposition techniques.

The bottom isolations 16 are respectively formed on the epitaxial portions 17 for electrical isolation. In some embodiments, each of the bottom isolations 16 includes or is made of silicon, silicon oxide, silicon nitride, carbon-doped silicon oxide, silicon oxycarbide, silicon oxynitride, silicon oxycarbon nitride, silicon carbon nitride, or combinations thereof. In some embodiments, formation of the bottom isolations 16 may include CVD, ALD, PVD, or other suitable deposition techniques, followed by an etching process to expose the second films 222′. In some embodiments, a thickness of each of the bottom isolations 16 in the Z direction may range from about 2 nm to about 8 nm.

In some embodiments, each of the source/drain portions 15 may include single crystalline silicon, single crystalline silicon germanium alloy, single crystalline silicon carbon alloy, single crystalline silicon carbon germanium alloy, polycrystalline silicon, polycrystalline silicon germanium, polycrystalline silicon carbon alloy, polycrystalline silicon carbon germanium alloy, or other suitable materials. The source/drain portions 15 may each be doped with an n-type dopant so as to function as a source or a drain of an n-MOSFET, or may be doped with a p-type dopant so as to function as a source or a drain of a p-MOSFET. The n-type dopant may be, for example, but not limited to, phosphorous (P, ³¹P), arsenic (As), antimony (Sb), other suitable materials, or combinations thereof. The p-type dopant may be, for example, but not limited to, boron or boron compound (for example, B, ¹¹B, BF₂), aluminum (Al), gallium (Ga), indium (In), other suitable p-type dopants, or combinations thereof. In some other embodiments, the source/drain portions 15 serving as sources or drains of n-MOSFETs may include or be made of silicon phosphide (SiP), silicon arsenide (SiAs), or a combination thereof, and the source/drain portions 15 serving as sources or drains of p-MOSFETs may include or be made of silicon boron (SiB). In some embodiments, formation of the source/drain portions 15 may include forming epitaxial regions to respectively fill the source/drain recesses 13 by an epitaxial growth process (such as molecular-beam epitaxy (MBE), selective area epitaxy (SAE), etc.), or other suitable deposition techniques. In some embodiments, an implantation process may be conducted after the epitaxial growth process to introduce the n-type dopant or the p-type dopant into the epitaxial regions. In some alternative embodiments, the implantation process may be omitted, and the n-type dopant or the p-type dopant may be in-situ doped in the epitaxial regions during the epitaxial growth process for forming the source/drain portions 15. In some embodiments, each of the source/drain portions 15 includes sub-layers L1, L2. The sub-layers L1, L2 of each of the source/drain portions 15 include the p-type dopants (or the n-type dopants) at different concentrations.

In some embodiments not shown herein, after formation of the inner spacers 14 and before formation of the source/drain portions 15, an etching process may be performed to reduce a dimension of the second films 222′ in the X direction while keeping the dummy structures 30 and the inner spacers 14 intact.

The isolation portions 40 are formed after formation of the source/drain portions 15. The isolation portions 40 are elongated in the Y direction and disposed to alternate with the dummy structures 30 in the X direction. Each of the isolation portions 40 is disposed to cover corresponding ones of the source/drain portions 15. To be specific, each of the isolation portions 40a, 40b, 40c is formed to cover a corresponding one of the source/drain portions 15a, a corresponding one of the source/drain portions 15b, a corresponding one of the source/drain portions 15c, and a corresponding one of the source/drain portions 15d. In some embodiments, each of the isolation portions 40 is further formed on the trench isolations 12. In some embodiments, each of the isolation portions 40 includes a contact etch stop layer (CESL) 401, an inter-layer dielectric (ILD) layer 402 (shown in FIG. 6B) and a cap layer 403 which are sequentially formed on the trench isolations 12 and the corresponding source/drain portions 15.

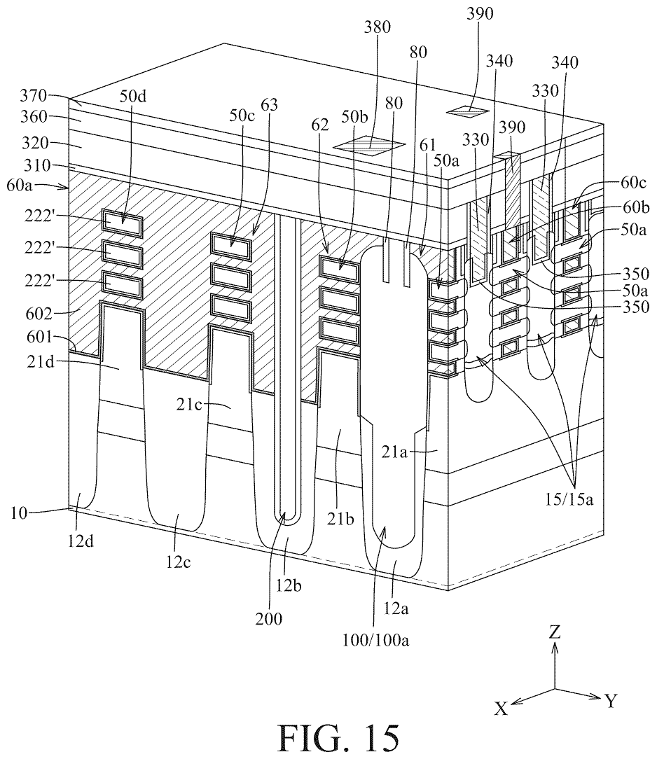

In some embodiments, the CESL 401 includes or is made of a dielectric material that is different from a dielectric material of the ILD layer 402, so that the CESL 401 may serve as an etch stop point during formation of metal contacts (e.g., the elements 330 shown in FIG. 15). In certain embodiments, possible dielectric materials suitable for the CESL 401 include silicon nitride, silicon oxynitride, silicon carbonnitride, other suitable dielectric materials, or combinations thereof. In some embodiments, the CESL 401 has a thickness ranging from about 2 nm to about 8 nm. In some embodiments, the ILD layer 402 (shown in FIG. 6B) includes or is made of silicon oxide, doped silicon oxide (e.g., phospho-silicate glass (PSG), boro-phospho-silicate glass (BPSG), fluoro-silicate glass (FSG), carbon-doped silicon oxide (SiCOH)), other suitable low-k dielectric materials, or combinations thereof. In some embodiments, in the case that an upper surface of the ILD layer 402 is located at a level lower than a level of an upper surface of each of the corresponding source/drain portions 15, the ILD layer 402 may be separated into ILD regions 402′ which are disposed to alternate with the corresponding source/drain portions 15. In some embodiments, the cap layer 403 includes or is made of a dielectric material that is different from the dielectric material of the ILD layer 402, so that the ILD layer 402 may be prevented from being damaged during removal of the dummy dielectric 302 of each of the dummy structures 30 (will be described in step S05). Possible dielectric materials suitable for the cap layer 403 are similar to those for the CESL 401, and thus details thereof are omitted for the sake of brevity. The material of the cap layer 403 may be different from that of the CESL 401.

In some embodiments, formation of each of the isolation portions 40 include multiple sub-steps as described in the following. Firstly, a first layer (not shown) for forming the CESL 401 and a second layer (not shown) for forming the ILD layer 402 are sequentially formed on the corresponding source/drain portions 15 and the dummy structures 30 using CVD, PVD, ALD, or other possible processes, followed by a planarization process (e.g., CMP) to expose the dummy gate 303 of each of the dummy structure 30. The first layer is formed into the CESL 401. The second layer is further etched back to have a reduced height in the Z direction by an etching process, thereby obtaining the ILD layer 402. In some embodiments, the ILD layer 402 is formed into the ILD regions 402′, and the CESL 401 is partially exposed from the ILD regions 402′. Afterwards, the cap layer 403 is formed on the ILD layer 402 and the CESL 401 (if exposed) using CVD, PVD, ALD, or other possible processes, followed by a planarization process (e.g., CMP) to expose the dummy gates 303 of each of the dummy structures 30.

Referring to FIG. 1 and the example illustrated in FIGS. 6A and 6B, the method 1 proceeds to step S05, where a replacement gate process is performed, thereby obtaining a patterned structure 2. FIG. 6A is a schematic perspective view similar to that of FIG. 5, but illustrating the structure after step S05. FIG. 6B is a schematic sectional view taken along line A-A′ of FIG. 6A in accordance with some embodiments.

In the replacement gate process, the dummy gate 303 and the dummy dielectric 302 in each of the dummy structures 30a, 30b, 30c (see FIG. 5) are removed to expose the stacking portions 22a′, 22b′, 22c′, 22d′. Then, the etched first films 221″ of the stacking portions 22a′, 22b′, 22c′, 22d′ are selectively removed, while the second films 222′ are substantially intact. Thus, channel portions 50 (including the channel portions 50a, 50b, 50c, 50d, see also FIG. 14E) are obtained. Each of the channel portions 50 includes three corresponding ones of the second films 222′ which are spaced apart from each other in the Z direction. In some embodiments, the second films 222′ may be also referred to as channel films. The channel portions 50a are formed on the fin base 21a and spaced apart from each other in the X direction, the channel portions 50b are formed on the fin base 21b and spaced apart from each other in the X direction, the channel portions 50c are formed on the fin base 21c and spaced apart from each other in the X direction, and the channel portions 50d are formed on the fin base 21d and spaced apart from each other in the X direction. Afterwards, gate structures 60 (including the gate structures 60a, 60b, 60c) are formed. The number of the gate structures 60 mainly depends on the number of the dummy structures 30. The gate structures 60 are each elongated in the Y direction and spaced apart from each other in the X direction. Each of the gate structures 60 is formed around the channel films 222′ of corresponding ones of the channel portions 50. To be specific, each of the gate structures 60a, 60b, 60c is formed around the channel films 222′ of a corresponding one of the channel portions 50a, the channel films 222′ of a corresponding one of the channel portions 50b, the channel films 222′ of a corresponding one of the channel portions 50c, and the channel films 222′ of a corresponding one of the channel portions 50d.

In some embodiments, each of the gate structures 60 includes a gate dielectric 601 and a gate electrode 602. The gate electrode 602 is separated from the corresponding stacks of the channel films 222′ by the gate dielectric 601. In some embodiments, the gate dielectric 601 includes a gate dielectric portion 611 disposed around the channel films 222′ of the corresponding channel portion 50a, a gate dielectric portion 621 disposed around the channel films 222′ of the corresponding channel portion 50b, a gate dielectric portion 631 disposed around the channel films 222′ of the corresponding channel portion 50c, and a gate dielectric portion 641 disposed around the channel films 222′ of the corresponding channel portion 50d. The gate electrode 602 includes gate electrode parts 612, 622, 632, 642 which are respectively formed on the gate dielectric portions 611, 621, 631, 641. The gate electrode 602 may include a work function metal. In some embodiments, the gate dielectric 601 includes a metal-containing high-k dielectric layer. The metal-containing high-k dielectric layer includes, for example, but not limited to, Hf-containing dielectric oxide materials, Ta-containing dielectric oxide materials (e.g., Ta₂O₅), Ti-containing dielectric oxide materials, Zr-containing dielectric oxide materials, Al-containing dielectric oxide materials (e.g., Al₂O₃), La-containing dielectric materials, other suitable materials (having a dielectric constant not less than about 9 or larger than about 30), or combinations thereof. In some embodiments, the gate dielectric 601 may have a thickness ranging from about 1 nm to about 3 nm. The materials (e.g. an electrically conductive material and the work function metal material) suitable for the gate electrode 602 may include, for example, but not limited to, a metal (e.g., copper, aluminum, titanium, tantalum, cobalt, tungsten, ruthenium, or the like, or alloys thereof), polysilicon, metal-containing nitrides (e.g., TiN, TaN), metal-containing silicides (e.g., NiSi), metal-containing carbides (e.g., TaC, TiAlC), or the like, or combinations thereof. In some embodiments, formation of the gate dielectric 601 and the gate electrode 602 includes multiple deposition processes (such as CVD, ALD, PVD, or other suitable deposition processes), multiple photolithography processes, multiple etching processes, multiple thermal processes, and multiple planarization processes (e.g., CMP) to expose the isolation portions 40, so that the gate electrode parts 612, 622, 632, 642 (or the gate dielectric portions 611, 621, 631, 641) may include different materials, or the gate dielectric portions 611, 621, 631, 641 may be doped with different dipoles for threshold voltage adjustment. Other suitable materials and processes for forming the gate dielectric 601 and the gate electrode 602 are within the contemplated scope of the present disclosure.

In some embodiments, prior to formation of the gate dielectric 601, interfacial layers 603 may be respectively formed on the channel films 222′. Each of the interfacial layers 603 serves to provide a good adhesion between the gate dielectric 601 and the respective channel film 222′. In some embodiments, the interfacial layers 603 are made of silicon oxide, and are formed by an oxidation reaction that happens on a surface portion of each of the channel films 222′. In some embodiments, each of the interfacial layers 603 has a thickness ranging from about 0.5 nm to about 2 nm. In some embodiments, after formation of the interfacial layers 603, a middle portion of each of the channel films 222′ which is surrounded by a corresponding one of the gate structures 60 has a height (H1, measured in the Z direction) ranging from about 5 nm to about 15 nm.

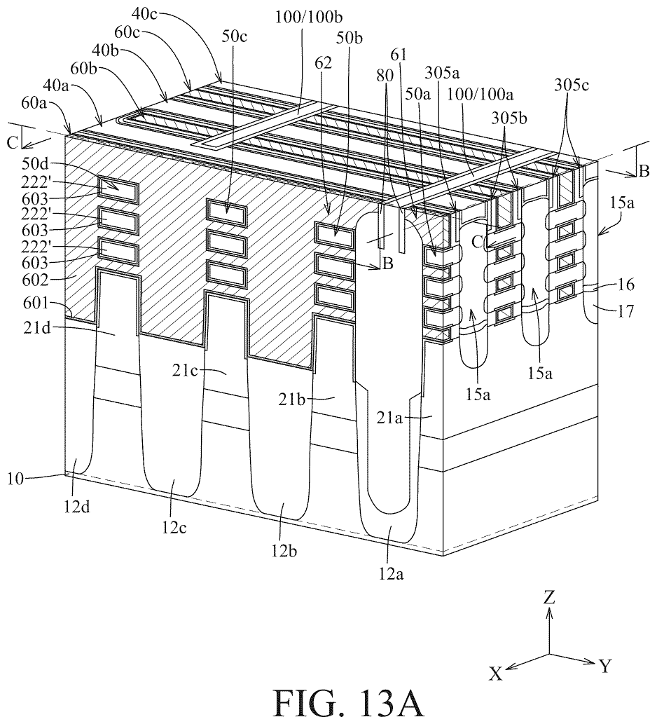

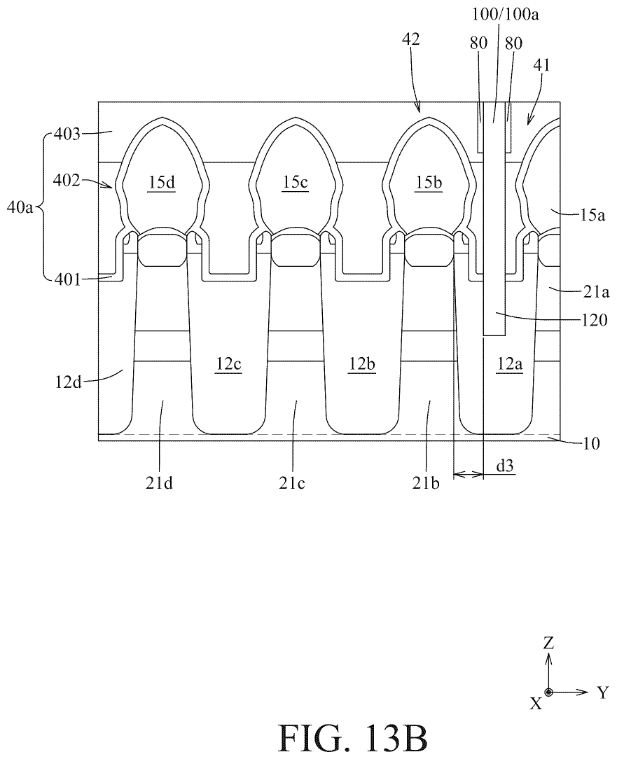

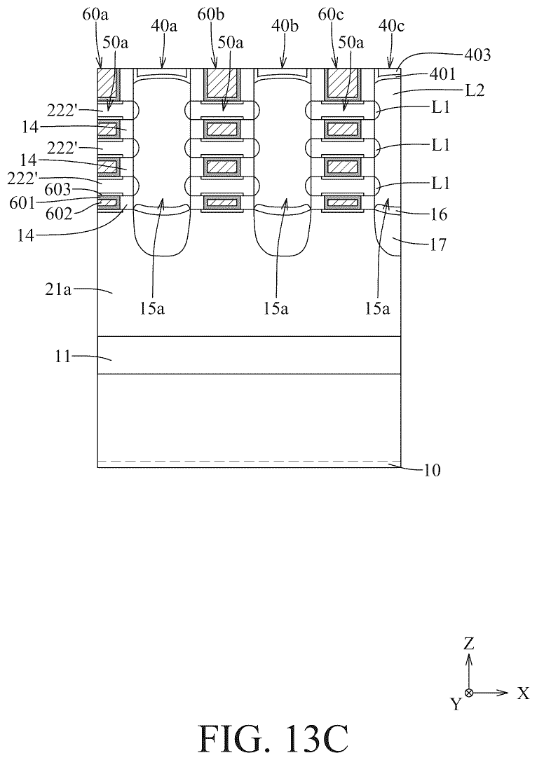

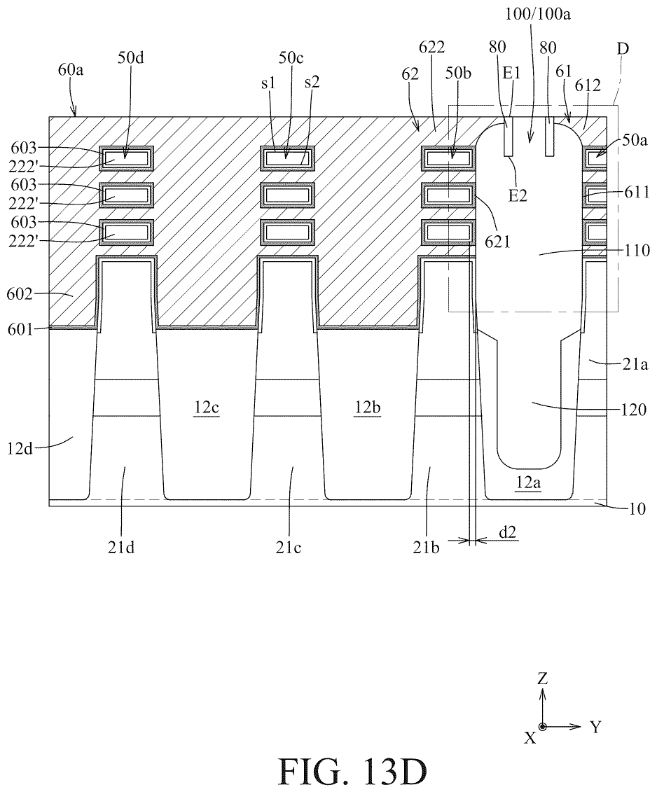

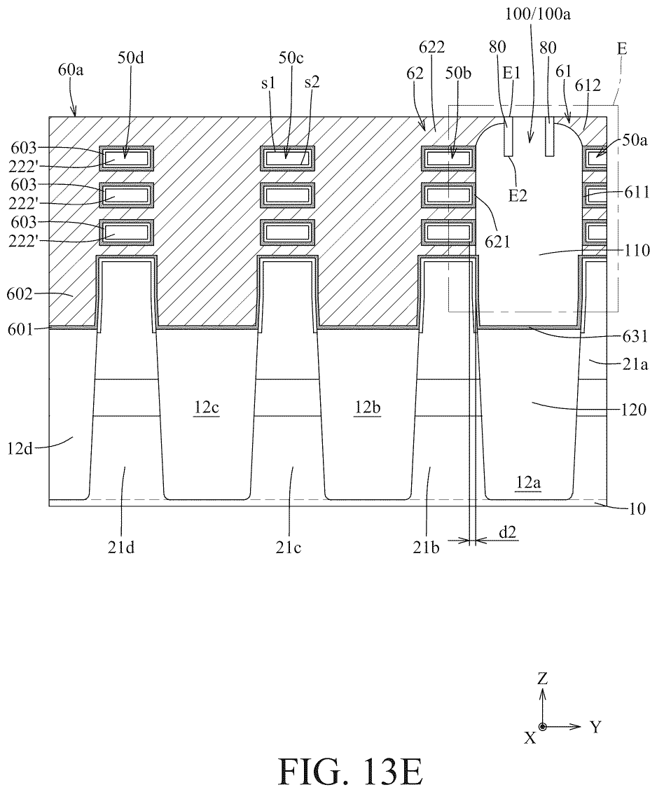

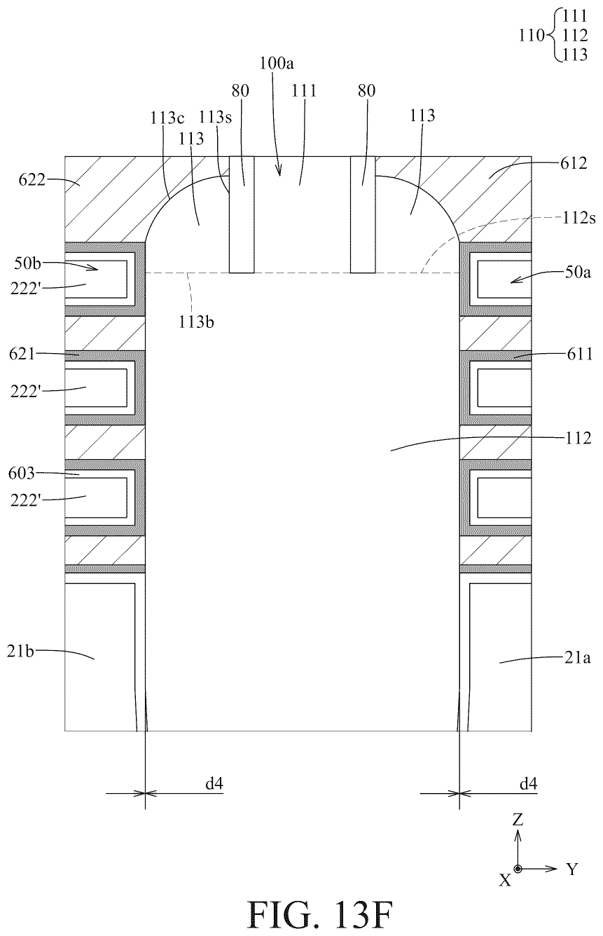

In the following steps (including steps S06 to step S11), dielectric walls 100 (including the dielectric walls 100a, 100b, shown in FIG. 13A), and a dielectric partition 200 (see FIG. 14A) are formed, and the details on the configuration and formation thereof will be described. The dielectric walls 100 and the dielectric partition 200 are each elongated in the X direction, and spaced apart from each other in the Y direction. The dielectric partition 200 is formed between the channel portions 50b and the channel portions 50c. The dielectric wall 100a is formed between the channel portions 50a and the channel portions 50b. The dielectric wall 100b has a configuration similar to a configuration of the dielectric wall 100a, except that the dielectric wall 100b is formed between the channel portions 50c and the channel portions 50d, and a length of the dielectric wall 100b measured in the X direction may be different from that of the dielectric wall 100a. Since the dielectric wall 100b may be formed in a manner similar to that for forming the dielectric wall 100a, the description regarding formation of dielectric walls 100 will focus solely on the formation of the dielectric wall 100a hereinafter.

Each of the dielectric wall 100a and the dielectric partition 200 exemplarily shown in FIG. 14A is formed in the gate structures 60a, 60b, 60c, the gate spacers 305a, 305b, 305c, and the isolation portions 40a, 40b, 40c (see also FIG. 6A). It is noted that the length of each of the dielectric wall 100a and the dielectric partition 200 may vary according to practical applications. That is, the number of the gate structures 60, the gate spacers 305 and the isolation portions 40 which the dielectric wall 100a (or the dielectric partition 200) will pass through is related to the length of the dielectric wall 100a (or the dielectric partition 200). Although the dielectric wall 100a and the dielectric partition 200 are each formed in the gate structures 60a, 60b, 60c, the gate spacers 305a, 305b, 305c and the isolation portions 40a, 40b, 40c, for purposes of simplicity and clarity, the description regarding formation of the dielectric wall 100a and the dielectric partition 200 will focus solely on the gate structure 60a, the gate spacer 305a and the isolation portion 40a hereinafter. Similarly, the channel portions 50a, 50b, 50c, 50d surrounded by the gate structure 60a and the source/drain portions 15a, 15b, 15c, 15d covered by the isolation portion 40a are described hereinafter, and the descriptions regarding the channel portions 50a, 50b, 50c, 50d surrounded by the gate structures 60b, 60c and the source/drain portions 15a, 15b, 15c, 15d covered by the isolation portions 40b, 40c are omitted.

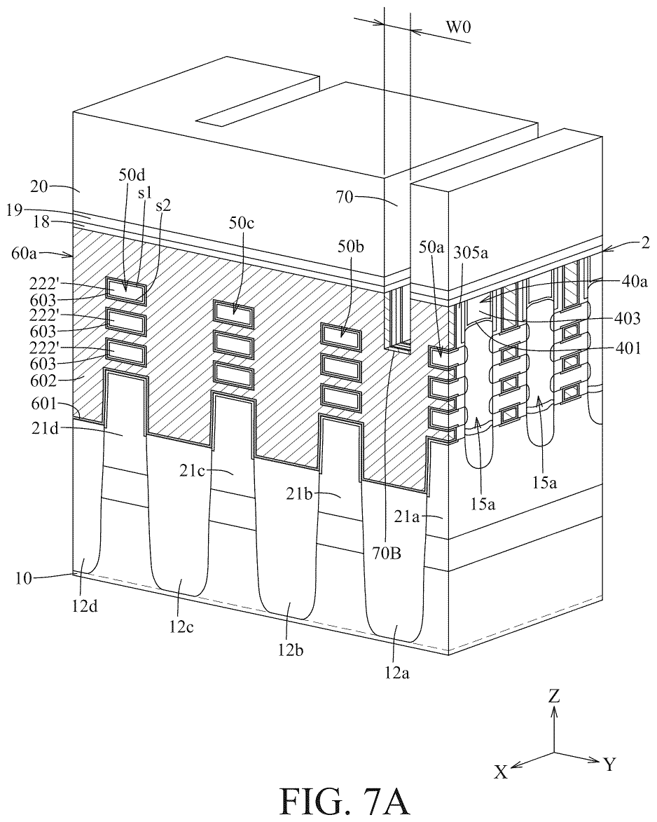

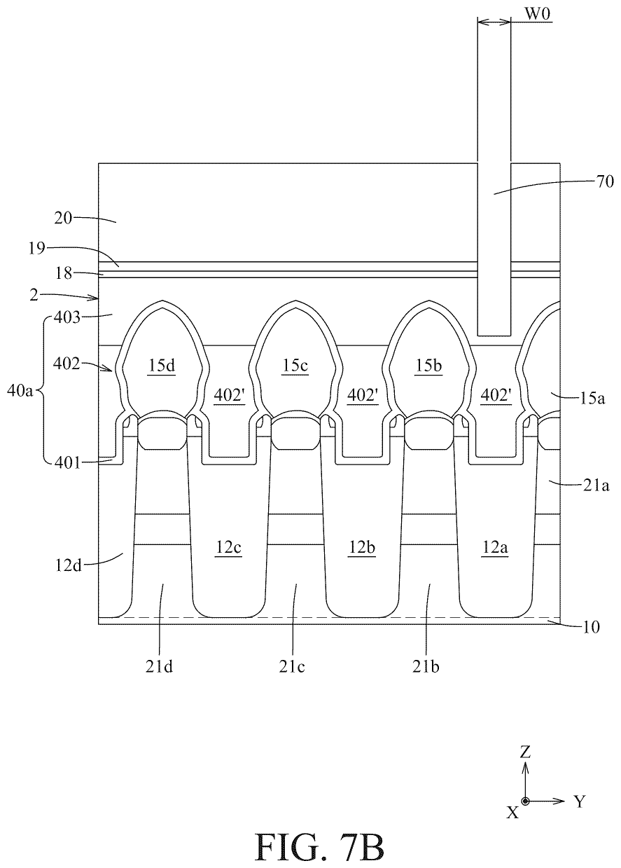

Referring to FIG. 1 and the examples illustrated in FIGS. 7A and 7B, the method 1 proceeds to step S06, where an upper trench 70 is formed in the patterned structure 2. FIGS. 7A and 7B are schematic views respectively similar to those of FIGS. 6A and 6B, but illustrating the structure after step S06.

The upper trench 70 is elongated in the X direction, and a projection of the upper trench 70 on the substrate 10 is not overlapped with a projection of each of the fin bases 21a, 21b on the substrate 10. In some embodiments, the upper trench 70 is formed in an upper portion of the gate electrode 602 of the gate structure 60a, an upper portion of the gate spacer 305a, and an upper portion of the cap layer 403 of the isolation portion 40a.

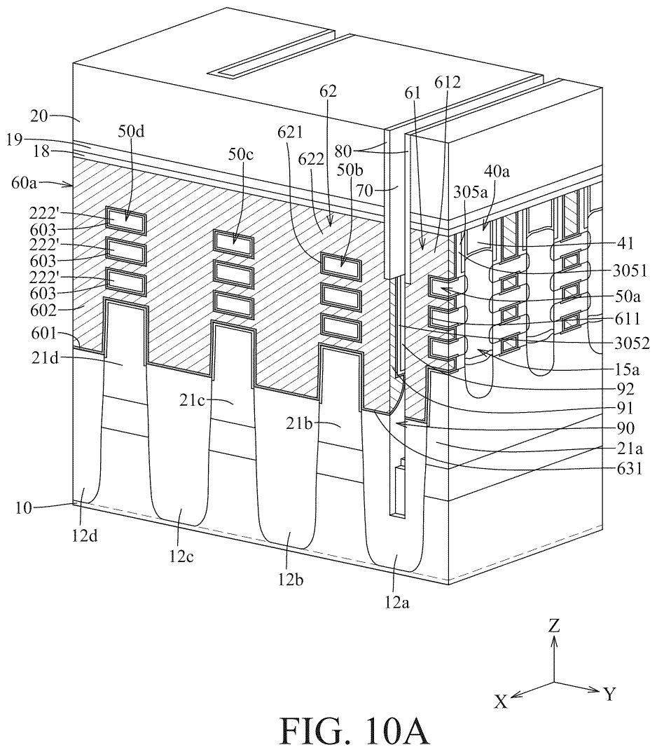

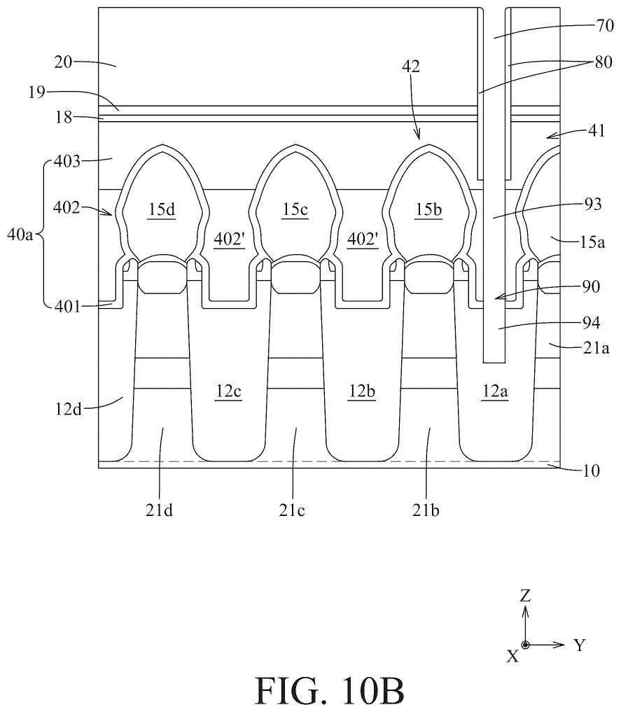

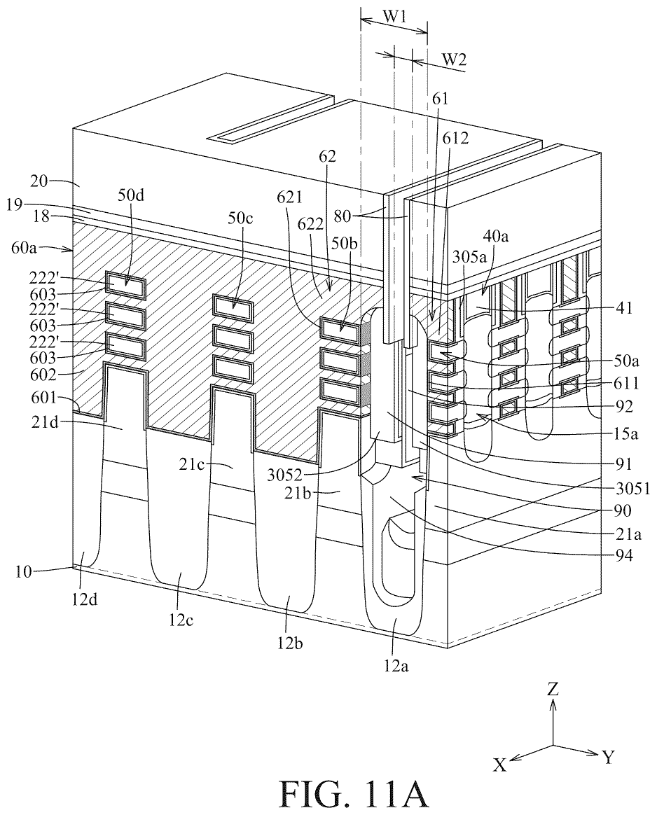

A width (W0) of the upper trench 70 measured in the Y direction is less than a distance between the channel portion 50a and the channel portion 50b, and is less than a minimum distance between the source/drain portion 15a and the source/drain portion 15b (see FIG. 14E), so that the channel portions 50a, 50b and the source/drain portions 15a, 15b can be prevented from being damaged during formation of a lower trench 90 (will be described in step S08 with reference to FIGS. 10A and 10B) which extends downwardly from the upper trench 70. In some embodiments, the width (W0) may range from about 8 nm to about 35 nm. In some embodiments, the upper trench 70 has a predetermined depth in the upper portion of the gate electrode 602, and the predetermined depth of the upper trench 70 is greater than zero. An uppermost one of the channel films 222′ in each of the channel portions 50a, 50b, 50c, 50d has an upper surface s1 and a lower surface s2 opposite to the upper surface s1. In some embodiments, a bottom 70B of the upper trench 70 is located at a level between a level of the upper surface s1 and a level of the lower surface s2.

Formation of the upper trench 70 may include multiple sub-steps as described in the following.

Firstly, a protection layer 18, a polish stop layer 19 and a hard mask layer 20 are sequentially formed on the patterned structure 2 by CVD, ALD, PVD, or other suitable deposition techniques. The protection layer 18 includes or is made of a dielectric material, and is used to prevent the gate electrode 602 from being oxidized. Possible dielectric materials suitable for the protection layer 18 and the hard mask layer 20 are similar to those for the cap layer 403, and thus details thereof are omitted for the sake of brevity. The polish stop layer 19 includes or is made of a material that is different from the dielectric material of the hard mask layer 20, for example, but not limited to, amorphous silicon. Afterwards, a patterned photoresist layer (not shown), which has a predetermined pattern, is formed on the hard mask layer 20 by a photolithography technique, so that portions of the hard mask layer 20 are exposed from the patterned photoresist layer. The photolithography technique may include a spin coating process, an exposure process, a development process, a baking process, and other suitable process. Next, a preliminary etching process (which may also be referred to as a first etching process) is performed to form the upper trench 70. The preliminary etching process is anisotropic (i.e., the etching mainly occurs in the Z direction). In some embodiments, the preliminary etching process may include dry etching, plasma etching, or other suitable etching techniques. In some embodiments, a precursor gas used in the preliminary etching process may include a fluorine-containing gas, such as CHₓF_{y}. During the preliminary etching process, the exposed portions of the hard mask layer 20 are removed, and other portions of the hard mask layer 20 protected by the patterned photoresist layer are not removed, so that the predetermined pattern of the patterned photoresist layer is transferred to the hard mask layer 20. Then, the polish stop layer 19, the protection layer 18, the gate electrode 602, the gate spacer 305a, and the cap layer 403 are etched using the patterned hard mask layer 20 as a mask, thereby obtaining the upper trench 70.

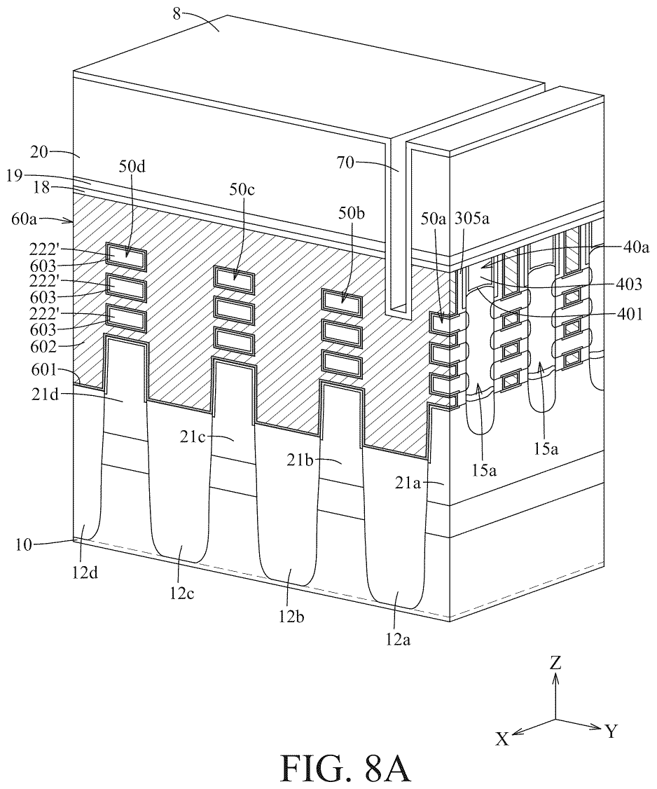

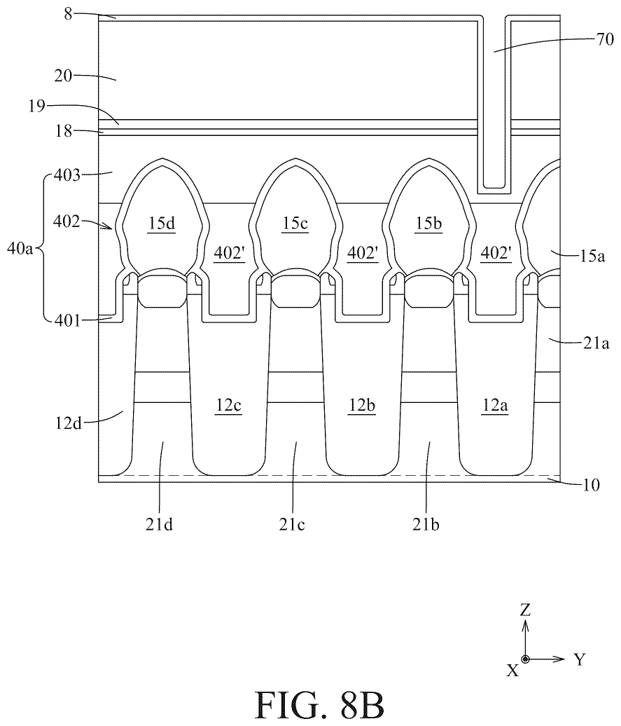

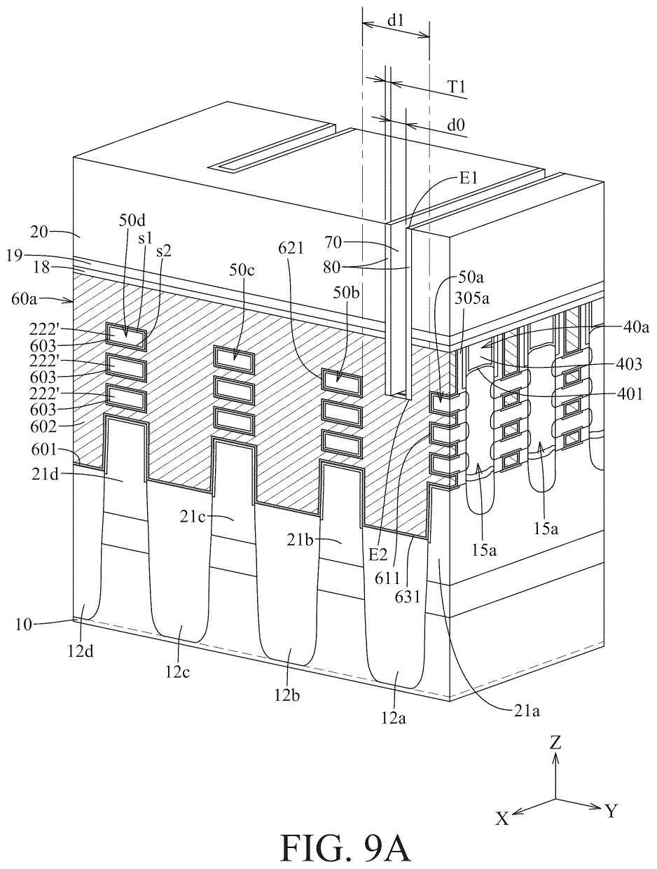

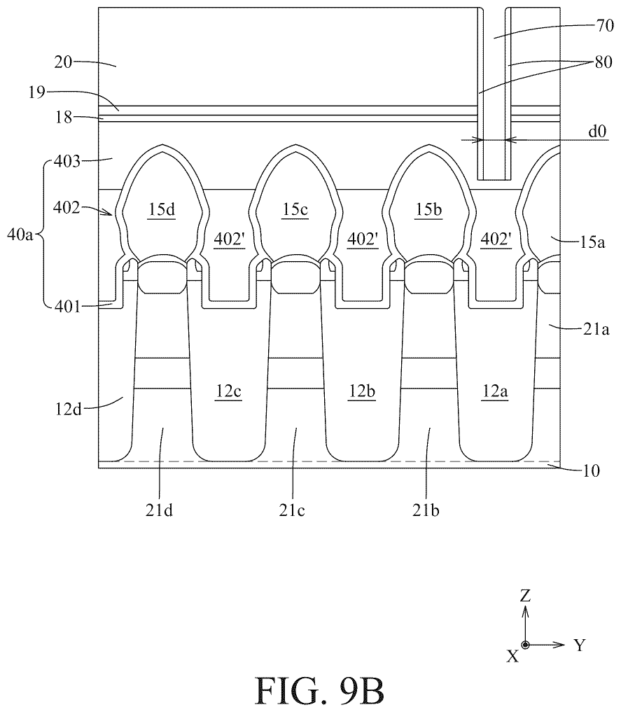

Referring to FIG. 1 and the examples illustrated in FIGS. 8A, 8B, 9A and 9B, the method 1 proceeds to step S07, where two dielectric liners 80 are respectively formed on two inner surfaces of the upper trench 70. FIGS. 9A and 9B are schematic views respectively similar to those of FIGS. 7A and 7B, but illustrating the structure after step S07. FIGS. 8A and 8B are schematic views respectively similar to those of FIGS. 7A and 7B, and illustrate one possible intermediate state in step S07 in accordance with some embodiments.

The dielectric liners 80 are spaced apart from each other in the Y direction. Formation of the dielectric liners 80 may include (i) conformally forming a dielectric layer 8 (see FIGS. 8A and 8B) on the structure shown in FIGS. 7A and 7B by CVD, PVD, ALD, or other possible processes, and (ii) preforming an anisotropic etching process on the dielectric layer 8 to remove horizontal portions of the dielectric layer 8, while leaving vertical portions of the dielectric layer 8 on the inner surfaces of the upper trench 70, thereby obtaining the dielectric liners 80. A distance (d0) between the dielectric liners 80 is less than a minimum distance (d1) between the gate dielectric portions 611, 621.

In some embodiments, each of the dielectric liners 80 includes or is made of silicon nitride, silicon oxide, silicon oxynitride, silicon oxycarbide, silicon oxycarbon nitride, silicon carbon nitride, other suitable dielectric materials, or combinations thereof. In some embodiments, each of the dielectric liners 80 has a thickness (T1) ranging from about 1 nm to about 5 nm. When each of the dielectric liners 80 is too thin (e.g., the thickness (T1) is less than about 1 nm), the dielectric liners 80 may be removed during formation of the lower trench 90 (step S08). When each of the dielectric liners 80 is too thick (e.g., the thickness (T1) is greater than about 5 nm), the lower trench 90 may not be well formed.

Each of the two dielectric liners 80 has an upper end E1 and a lower end E2 which are opposite to each other and which are respectively distal from and proximate to the substrate 10. The location of the lower end E2 depends on the predetermined depth of the upper trench 70. In some embodiments, a level of the lower end E2 is located between the level of the upper surface s1 and the level of the lower surface s2 (see FIG. 7A).

Referring to FIG. 1 and the examples illustrated in FIGS. 10A and 10B, the method 1 proceeds to step S08, where a lower trench 90 which extends downwardly from the upper trench 70 is formed by a main etching process (which may also be referred to as a second etching process). FIGS. 10A and 10B are schematic views respectively similar to those of FIGS. 9A and 9B, but illustrating the structure after step S08.

The main etching process is anisotropic (i.e., the etching mainly occurs in the Z direction). In some embodiments, the preliminary etching process may include dry etching, plasma etching, or other suitable etching techniques. In some embodiments, the main etching process includes multiple deposition-etching cycles, each of which includes a deposition step and an etching step. A precursor gas used in the deposition step includes silicon-containing gas (such as SiCl₄) and O₂. A precursor gas used in the etching step includes Cl₂, BCl₃, CH₄, CF₄, C₄F₆, O₂, and combinations thereof. The etching step is conducted to deepen the lower trench 90, and a dielectric layer (such as silicon oxide) is formed on an inner surface of the lower trench 90 during the deposition step so as to prevent the lower trench 90 from being widened when the lower trench 90 is deepened.

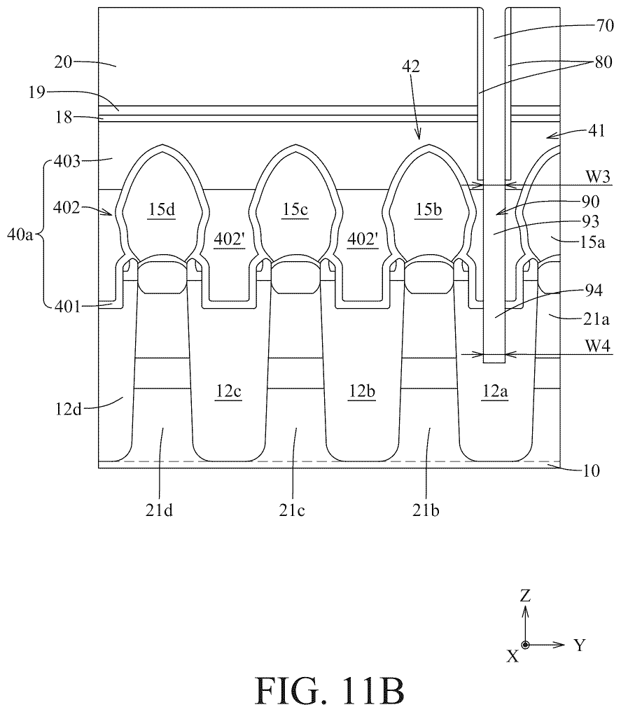

After step S08, as shown in FIG. 10A, the gate structure 60a is divided into two gate segments 61, 62 which are separated from each other by the upper trench 70 and the lower trench 90. The gate segment 61 and the gate segment 62 are respectively formed around the channel portion 50a and the channel portion 50b. The gate segment 61 includes the gate electrode part 612 and the gate dielectric portion 611. The gate segment 62 includes the gate electrode part 622 and the gate dielectric portion 621. It is noted that, before proceeding to step S09, the gate dielectric portions 611, 621 are prevented from being exposed to the upper trench 70 and the lower trench 90. As shown in FIG. 10B, the isolation portion 40a is divided into two isolation parts 41, 42 which are separated from each other by the upper trench 70 and the lower trench 90. The isolation part 41 and the isolation part 42 are respectively formed on the source/drain portion 15a and the source/drain portion 15b. The gate spacer 305a is divided into two spacer parts 3051, 3052 (see also FIG. 11A) which are separated from each other by the upper trench 70 and the lower trench 90.

Referring back to FIG. 9A, in some embodiments, the gate dielectric 601 of the gate structure 60a further includes a bottom gate dielectric portion 631 which is disposed on the fin bases 21a, 21b and the trench isolation 12a. In some embodiments as shown in FIGS. 10A and 10B, the lower trench 90 is formed to penetrate the bottom gate dielectric portion 631 so as to terminate at the trench isolation 12a. In some other embodiments not shown herein, the lower trench 90 terminates at the bottom gate dielectric portion 631 without passing through the bottom gate dielectric portion 631.

Referring to FIG. 1 and the examples illustrated in FIGS. 11A and 11B, the method 1 proceeds to step S09, where the lower trench 90 is widened by a selective etching process (which may also be referred to as a third etching process). FIGS. 11A and 11B are schematic views respectively similar to those of FIGS. 10A and 10B, but illustrating the structure after step S09.

In some embodiments, the selective etching process may include dry etching, wet etching, other suitable etching techniques, or combinations thereof. In some embodiments, etchant(s) used in the selective etching process having a relatively high etching selectivity to the material(s) of the gate electrode parts 612, 622. The etchant(s) used in the selective etching process may be gas-phase, liquid-phase, or other suitable states. In some embodiments, the etchant(s) used in the selective etching process includes a mixture of NH₄OH, H₂O₂ and H₂O.

During the selective etching process, the gate segments 61, 62 are etched back, while the spacer parts 3051, 3052, the isolation parts 41, 42, the trench isolation 12a, and the dielectric liners 80 are substantially intact due to different etching selectivity ratios. To be specific, the electrode gate parts 612, 622 are etched back at a first etch rate, and the spacer parts 3051, 3052 (or the isolation parts 41, 42, the trench isolation 12a) are etched back at a second etch rate. The second etch rate is lower than the first etch rate.

In other words, the lower trench 90 (see FIGS. 10A and 10B, before the selective etching process) has a trench region 91 located between the gate segments 61, 62, a trench region 92 located between the spacer parts 3051, 3052, a trench region 93 (shown in FIG. 11B) located between the isolation parts 41, 42, and a trench region 94 located in the trench isolations 12a between the fin bases 21a, 21b. During the selective etching process, the trench region 91 is widened. Therefore, after the selective etching process, a maximum width (W1, see FIG. 11A) of the trench region 91 measured in the Y direction (i.e., a maximum distance between the gate electrode parts 612, 622) is greater than a minimum width (W4, see FIG. 11B) of the trench region 94 measured in the Y direction. The trench region 92 has a width (W2, see FIG. 11A) measured in the Y direction (i.e., a distance between the spacer parts 3051, 3052). The trench region 93 has a width (W3, see FIG. 11B) measured in the Y direction (i.e., a distance between the isolation parts 41, 42). The widths (W2, W3, W4) are substantially equal to each other. In some embodiments, each of the widths (W2, W3, W4) is substantially equal to the distance (d0, see FIG. 9A). In some embodiments, the maximum width (W1) of the trench region 91 is about 4 nm to about 24 nm and is much greater than the distance (d0).

Before the selective etching process, as shown in FIG. 10A, each of the gate electrode parts 612, 622 has an upper region which is located aside a respective one of the dielectric liners 80, and a lower region which is located beneath the upper region without being covered by the respective one of the dielectric lines 80. During the selective etching process, the upper region of each of the gate electrode parts 612, 622 is protected by a respective one of the dielectric liners 80, and the lower region of each of the gate electrode parts 612, 622 is etched to widen the trench region 91 of the lower trench 90. Therefore, after the selective etching process, the maximum width (W1) of the trench region 91 is greater than the width (W0, see FIG. 7A) of the upper trench 70, and each of the width (W0) of the upper trench 70 and the distance (do, see FIG. 9A) between the dielectric liners 80 is kept constant from the main etching process to the selective etching process. In other words, values of the width (W0) before and after the selective etching process are substantially the same, and values of the distance (d0) before and after the main etching process are substantially the same.

It is noted that, although a side surface of the upper region of each of the gate electrode parts 612, 622 is protected by the respective one of the dielectric liners 80, a bottom surface of the upper region of each of the gate electrode parts 612, 622 may be exposed to the trench region 91 once the trench region 91 is widened, and thus the upper region of each of the gate electrode parts 612, 622 may also be etched back from the bottom surface thereof during the selective etching process. After the selective etching process, the upper region of each of the gate electrode parts 612, 622 is kept to be in contact with the respective one of the dielectric liners 80, and has a thickness (measured in the Z direction) that gradually decreases in a direction toward the respective one of the dielectric liners 80. In some embodiments, a minimum thickness of the upper region of each of the gate electrode parts 612, 622 measured in the Z direction is greater than about 4.5 nm.

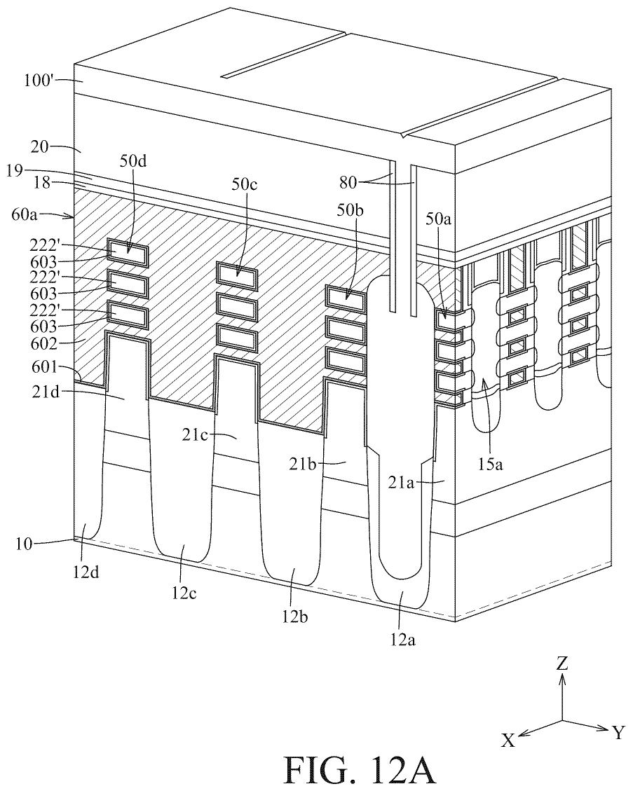

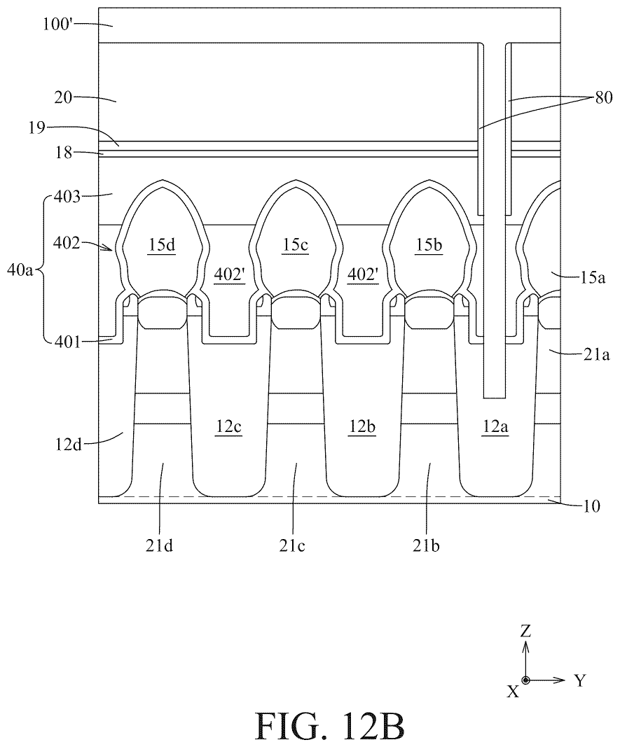

Referring to FIG. 1 and the examples illustrated in FIGS. 12A to 13D, the method 1 proceeds to step S10, where the dielectric wall 100a is formed in the upper trench 70 and the lower trench 90. FIGS. 13A and 13B are schematic views respectively similar to those of FIGS. 11A and 11B, but illustrating the structure after step S10. FIGS. 12A and 12B are schematic views respectively similar to those of FIGS. 11A and 11B, and illustrate one possible intermediate state in step S10 in accordance with some embodiments. FIG. 13C is a schematic sectional view taken along line B-B′ of FIG. 13A. FIG. 13D is a schematic sectional view taken along line C-C′ of FIG. 13A.

Formation of the dielectric wall 100 may include (i) forming a dielectric layer 100′ (see FIGS. 12A and 12B) on the structure shown in FIGS. 11A and 11B by CVD, PVD, ALD, or other possible deposition processes to fill the upper trench 70 and the lower trench 90 (see FIGS. 11A and 11B), and (ii) preforming a planarization process (e.g., CMP) on the dielectric layer 100′ to expose the gate electrode parts 612, 622, thereby obtaining the dielectric wall 100a. Possible dielectric materials suitable for the dielectric wall 100a are similar to those for the dielectric liners 80, and thus the details thereof are omitted for the sake of brevity. In some embodiments, the dielectric wall 100a may be configured as a single layer structure or a multi-layered structure.

In some embodiments, referring to FIG. 13D, the dielectric wall 100a includes an upper wall portion 110 which is formed between the gate parts 612, 622, and a lower wall portion 120 which is disposed beneath the upper wall portion 110 and which is formed in the trench isolation 12a. A minimum distance (d2) from the upper wall portion 110 to the channel portion 50b is less than a maximum distance (d3, shown in FIG. 13B) from the lower wall portion 120 to the fin base 21b. The upper end E1 of each of the two dielectric liners 80 is flush with an upper surface of the upper wall portion 110. In some embodiments, the upper wall portion 110 and the lower wall portion 120 have a total height (measured in the Z direction) ranging from about 100 nm to about 180 nm.

FIG. 13E is a schematic sectional view similar to that of FIG. 13D, but the dielectric wall 100a terminates at the bottom gate dielectric portion 631 without passing through the bottom gate dielectric portion 631 in accordance with some other embodiments. In such case, the lower trench 90 formed in step S08 is terminated at the bottom gate dielectric portion 631 and the lower wall portion 120 shown in FIG. 13D is absent in FIG. 13E.

FIG. 13F is an enlarged fragmentary view of area D shown in FIG. 13D or area E shown in FIG. 13E. The upper wall portion 110 includes a first wall region 111, a second wall region 112 and two side regions 113. In some embodiments, the two dielectric liners 80 may be together referred to as a dielectric unit. The first wall region 111 is located between the two dielectric liners 80 and has the upper surface of the upper wall portion 110. A width of the first wall region 111 measured in the Y direction is substantially equal to the distance (do, see FIGS. 9A and 9B). The second wall region 112 is located beneath the first wall region 111. The two side regions 113 extend from an upper surface 112s of the second wall region 112 and are respectively located at two opposite sides of the dielectric unit in the Y direction. In some embodiments, each of the side regions 113 has a side surface 113s that is in contact with a respective one of the dielectric liners 80, a bottom surface 113b that is in contact with the upper surface 112s of the second wall region 112, and an interconnect surface 113c interconnecting an upper edge of the side surface 113s and an outer edge of the bottom surface 113b. In some embodiments, the interconnect surface 113c is convex upward to form a convex surface.

In some embodiments, in the case that the gate dielectric portion 611 (or the gate dielectric portion 621) are exposed to the lower trench 90 after the selective etching process (step S09, see FIG. 11A), a minimum distance (d4) between the dielectric wall 100a and the gate dielectric portion 621 (or the gate dielectric portion 611) is substantially equal to zero. In some other embodiments not shown herein, in the case that the gate dielectric portions 611, 621 are not exposed to the lower trench 90 after the selective etching process, a minimum distance (d4) between the dielectric wall 100a and the gate dielectric portion 621 (or the gate dielectric portion 611) is greater than zero. In certain embodiments, the minimum distance (d4) may not be greater than about 6 nm.

For purposes of simplicity and clarity, only the structure shown in FIGS. 14A to 14D is used to illustrate the following steps.

Referring to FIG. 1 and the examples illustrated in FIGS. 14A to 14D, the method 1 proceeds to step S11, where the dielectric partition 200 is formed, thereby obtaining the semiconductor structure 3. FIGS. 14A to 14D are schematic views respectively similar to those of FIGS. 13A to 13D, but illustrating the structure after step S11. FIG. 14E is a schematic cross-sectional view taken along line G-G′ of FIG. 14A.

In some embodiments, the dielectric partition 200 is formed after formation of the dielectric wall 100a. In some other embodiments, the dielectric partition 200 is formed before the preliminary etching process.

In some embodiments, the dielectric partition 200 may be formed in a manner similar to that as described in steps S06, S08 and S10, except that a deep trench (not shown) for filling the dielectric partition 200 therein is formed in the gate structure 60a between the channel portions 50b, 50c and extends into the trench isolation 12b. In some embodiments, the deep trench is elongated in the X direction, so that the deep trench is formed in the gate spacer 305a and the isolation portion 40a and is located between the source/drain portions 15b, 15c. To be specific, the deep trench may be formed by a photolithography process, followed by the preliminary etching process (as described in step S06) and the main etching process (as described in step S08), and the dielectric partition 200 is formed in the deep trench using CVD, PVD, ALD, or other possible deposition processes, followed by a planarization process (e.g., CMP). In some embodiments, the deep trench is not widened by an etching process, such as the selective etching process as described in step S09. Possible dielectric materials suitable for the dielectric partition 200 are similar to those for the dielectric wall 100a, and thus the details thereof are omitted for the sake of brevity. In some embodiments, the dielectric partition 200 may be configured as a single layer structure or a multi-layered structure. In some embodiments, as shown in FIG. 14A, the dielectric partition 200 is formed as a bi-layered structure including an outer sub-layer 2000 and an inner sub-layer 200i. In some embodiments, the outer sub-layer 2000 is made of silicon nitride, and the inner sub-layer sub-layer 200i is made of silicon oxide, or other suitable low-k dielectric materials. In some embodiments, a width of the dielectric partition 200 measured in the Y direction may be greater than the width (W0, see FIG. 7A) of the upper trench 70 and less than the width (W1, see FIG. 11A) of the trench region 91.

After formation of the dielectric partition 200, the gate structure 60a is formed into the gate segments 61, 62 and a gate segment 63. The gate segment 62 is formed between the dielectric wall 100a and the dielectric partition 200. The gate segment 62 is separated from the gate segment 63 by the dielectric partition 200, and is separated from the gate segment 61 by the dielectric wall 100a. The gate segment 63 is formed around the channel portions 50c, 50d. The gate segment 63 includes the gate electrode parts 632, 642, and the gate dielectric portions 631, 641.

In some embodiments, after formation of the dielectric partition 200, the isolation portion 40a is divided into the isolation parts 41, 42 and an isolation part 43. The isolation part 42 is separated from the isolation part 43 by the dielectric partition 200, and is separated from the isolation part 41 by the dielectric wall 100a. In some embodiments, after formation of the dielectric partition 200, the gate spacer 305a is divided into the spacer parts 3051, 3052 and a spacer part 3053. The spacer part 3052 is separated from the spacer part 3053 by the dielectric partition 200, and is separated from the spacer part 3051 by the dielectric wall 100a.

Referring to FIG. 14D, the channel portion 50b is located between the dielectric wall 100a and the dielectric partition 200. A minimum distance (d5) from the channel portion 50b to the dielectric wall 100a is less than a minimum distance (d6) from the channel portion 50b to the dielectric partition 200.

Referring to FIG. 14E, the dielectric partition 200 has a uniform width measured in the Y direction, while the dielectric wall 100a has different widths measured in the Y direction at different locations.

In some embodiments, some steps in the method 1 may be modified, replaced, or eliminated without departure from the spirit and scope of the present disclosure. In some alternative embodiments, the semiconductor structure 3 may further include additional features, and/or some features present in the semiconductor structure 3 may be modified, replaced, or eliminated without departure from the spirit and scope of the present disclosure.

For example, in some embodiments, formation of the dielectric liners 80 (step S07) may be omitted. In such case, the side regions 113 shown in FIG. 13F are absent in the upper wall portion, and a width of the first wall region measured in the Y direction may be the same as a width of the second wall region measured in the Y direction.

Furthermore, in some embodiments, as shown in FIG. 15, the semiconductor structure 3 may be further formed with a middle-end interconnect structure thereon. In some embodiments, formation of the middle-end interconnect structure include multiple sub-steps in the following. Firstly, a protection layer 310 is formed on the structure shown in FIG. 14A by CVD, ALD, PVD, or other suitable deposition techniques, so as to prevent the gate electrode 602 of each of the gate structures 60a, 60b, 60c from being oxidized. The protection layer 310 includes or is made of a dielectric material that is similar to the dielectric materials suitable for the protection layer 18. Afterwards, a dielectric layer 320 is formed on the protection layer 310 by CVD, ALD, PVD, or other suitable deposition techniques. Possible dielectric materials suitable for the dielectric layer 320 are similar to those for the ILD layer 402, and thus details thereof are omitted for the sake of brevity. Next, metal contacts 330 (two of which are exemplarily shown in FIG. 15) are formed. Each of the metal contacts 330 extends downwardly through the dielectric layer 320, the protection layer 310 and one of the isolation portions 40, so as to connect to a corresponding lower one of the source/drain portions 15. In some embodiments, the metal contacts 330 may include a conductive material, such as tungsten (W), aluminum (Al), ruthenium (Ru), cobalt (Co), copper (Cu), palladium (Pd), nickel (Ni), platinum (Pt), a low resistivity metal constituent, etc., or combinations thereof. In some embodiments, silicon nitride re-deposition (SNR) layers 340 are each formed to separate one of the metal contacts 330 from the dielectric layer 320, the protection layer 310 and a corresponding one of the isolation portions 40. In some embodiments, metal silicide layers 350 are each formed between one of the metal contacts 330 and a corresponding lower one of the source/drain portions 15, so as to reduce a contact resistance (Rcsd) between the one of the metal contacts 330 and the corresponding lower one of the source/drain portions 15. In some embodiments, the metal silicide layers 350 may be made of a metal silicide including titanium (Ti), nickel (Ni), cobalt (Co), ruthenium (Ru), molybdenum (Mo), or combinations thereof. The material(s) of the metal silicide layers 350 may vary according to the material(s) of the corresponding lower one of the source/drain portions 15 to be connected. After formation of the metal contacts 330, dielectric layers 360, 370 are sequentially formed on the dielectric layer 320 by CVD, ALD, PVD, or other suitable deposition techniques. Possible dielectric materials suitable for the dielectric layers 360, 370 are similar to those for the dielectric layer 320, and thus details thereof are omitted for the sake of brevity. It is noted that the dielectric layer 360 includes or is made of a dielectric material that is different from the dielectric material of each of the dielectric layers 320, 370. Thereafter, via contacts 380, 390 (one via contact 380 and two via contacts 390 are exemplarily shown in FIG. 15) are formed. The via contact 380 extends downwardly through the dielectric layers 360, 370 so as to connect to a corresponding lower one of the metal contacts 330. Each of the via contacts 390 extends downwardly through the dielectric layers 360, 370 so as to connect to the gate electrode 602 of a corresponding lower one of the gate structures 60. Possible conductive materials suitable for the via contacts 380, 390 are similar to those for the metal contacts 330, and thus the details thereof are omitted for the sake of brevity.

In summary, since the dielectric walls 100 are formed after the replacement gate process, the method 1 is highly compatible with a gate-all-around (GAA) transistor manufacturing process. In addition, the dielectric walls 100 can be flexibly applied in a device cell having a GAA-based structure, so that a cell boundary of the device cell in the Y direction can be effectively reduced.

In accordance with some embodiments of the present disclosure, a method for manufacturing a semiconductor structure includes: forming a patterned structure which includes a first protrusion and a second protrusion which are spaced apart from each other, a first channel portion and a second channel portion respectively formed on the first protrusion and the second protrusion, a gate electrode which surrounds the first channel portion and the second channel portion, and a gate dielectric including a first gate dielectric portion which is disposed to separate the gate electrode from the first channel portion, and a second gate dielectric portion which is disposed to separate the gate electrode from the second channel portion; performing a first etching process to form an upper trench in an upper portion of the gate electrode; performing a second etching process on a lower portion of the gate electrode through the upper trench, so that the gate electrode is formed into two gate parts which are separated from each other by the upper trench and a lower trench that extends downwardly from the upper trench, the two gate parts being respectively formed on the first channel portion and the second channel portion; performing a third etching process on the two gate parts to widen the lower trench; and after the third etching process, forming a dielectric wall in the upper trench and the lower trench.

In accordance with some embodiments of the present disclosure, the patterned structure further includes a trench isolation which is formed between the first protrusion and the second protrusion, and the gate dielectric further includes a bottom gate dielectric portion formed on the trench isolation. In the second etching process, the lower trench is terminated at the bottom gate dielectric portion.

In accordance with some embodiments of the present disclosure, the patterned structure further includes a trench isolation which is formed between the first protrusion and the second protrusion, and the gate dielectric further includes a bottom gate dielectric portion formed on the trench isolation. In the second etching process, the lower trench is formed to penetrate the bottom gate dielectric portion so as to terminate at the trench isolation.

In accordance with some embodiments of the present disclosure, the first protrusion and the second protrusion are spaced apart from each other in a first direction. The lower trench has a first trench region formed between the two gate parts and a second trench region formed in the trench isolation. After the third etching process, a maximum width of the first trench region measured in the first direction is greater than a minimum width of the second trench region measured in the first direction.

In accordance with some embodiments of the present disclosure, after the first etching process and before the second etching process, the method further includes: forming two dielectric liners respectively on two inner surfaces of the upper trench such that a distance between the two inner surfaces of the upper trench is kept constant from the second etching process to the third etching process.

In accordance with some embodiments of the present disclosure, the first channel portion has an upper surface and a lower surface opposite to the upper surface, and a bottom of the upper trench formed in the first etching process is located at a level between a level of the upper surface of the first channel portion and a level of the lower surface of the first channel portion.

In accordance with some embodiments of the present disclosure, a distance between the two dielectric liners is less than a distance between the first gate dielectric portion and the second gate dielectric portion.

In accordance with some embodiments of the present disclosure, the first protrusion and the second protrusion are spaced apart from each other in a first direction. During the third etching process, an upper region of each of the two gate parts is protected by a respective one of the two dielectric liners, and a lower region of each of the two gate parts is etched to widen the lower trench. After the third etching process, a minimum width of the upper trench measured in the first direction is less than a maximum width of the lower trench measured in the first direction.

In accordance with some embodiments of the present disclosure, after the third etching process, the first gate dielectric portion and the second gate dielectric portion are exposed to the lower trench.

In accordance with some embodiments of the present disclosure, a method for manufacturing a semiconductor structure includes: forming a patterned structure which includes a first protrusion and a second protrusion which are spaced apart from each other, a first channel portion and a second channel portion respectively formed on the first protrusion and the second protrusion, and a gate structure which is disposed around the first channel portion and the second channel portion; performing a first etching process to form an upper trench in an upper portion of the gate structure; performing a second etching process on a lower portion of the gate structure, so that the gate structure is formed into a first segment and a second segment which are separated from each other by the upper trench and a lower trench that extends downwardly from the upper trench, the first segment and the second segment being respectively formed around the first channel portion and the second channel portion; performing a third etching process on the first segment and the second segment so as to widen the lower trench; and after the third etching process, forming a dielectric wall in the upper trench and the lower trench.

In accordance with some embodiments of the present disclosure, the method further includes: forming a dielectric partition in the gate structure such that the second channel portion is located between the dielectric wall and the dielectric partition. A minimum distance from the second channel portion to the dielectric wall is less than a minimum distance from the second channel portion to the dielectric partition.

In accordance with some embodiments of the present disclosure, the dielectric partition is formed before the first etching process.

In accordance with some embodiments of the present disclosure, the dielectric partition is formed after formation of the dielectric wall. The second segment is disposed between the dielectric partition and the dielectric wall.

In accordance with some embodiments of the present disclosure, the first protrusion and the second protrusion are spaced apart from each other in a first direction. The patterned structure further includes a first source/drain portion connected to the first channel portion, a second source/drain portion connected to the second channel portion, and an isolation portion which is formed to cover the first source/drain portion and the second source/drain portion and which is located adjacent to the gate structure. The upper trench is elongated in a second direction and is formed in an upper portion of the isolation portion. The second direction is transverse to the first direction.

In accordance with some embodiments of the present disclosure, in the second etching process, the isolation portion is formed into a first isolation part and a second isolation part which are separated from each other by the upper trench and the lower trench, and which are respectively formed on the first source/drain portion and the second source/drain portion.

In accordance with some embodiments of the present disclosure, the first segment includes a first gate part and a first gate dielectric portion which is disposed to separate the first gate part from the first channel portion, and the second segment includes a second gate part and a second gate dielectric portion which is disposed to separate the second gate part from the second channel portion. During the third etching process, the first gate part and the second gate part are etched back at a first etch rate, and the first isolation part and the second isolation part are etched back at a second etch rate that is less than the first etch rate.

In accordance with some embodiments of the present disclosure, after the third etching process, the lower trench has a first width measured in the first direction between the first gate part and the second gate part and a second width measured in the first direction between the first isolation part and the second isolation part. The first width is greater than the second width.

In accordance with some embodiments of the present disclosure, a semiconductor structure includes: a first protrusion and a second protrusion spaced apart from each other; a trench isolation formed between the first protrusion and the second protrusion; a first channel portion and a second channel portion respectively formed on the first protrusion and the second protrusion; a first gate part and a second gate part which are respectively formed on the first protrusion and the second protrusion and which are respectively formed around the first channel portion and the second channel portion; and a dielectric wall including an upper wall portion which is formed between the first gate part and the second gate part, and a lower wall portion which is disposed beneath the upper wall portion and which is formed in the trench isolation. A minimum distance from the upper wall portion to the second channel portion is less than a maximum distance from the lower wall portion to the second protrusion.

In accordance with some embodiments of the present disclosure, the first protrusion and the second protrusion are spaced apart from each other in a first direction. The upper wall portion includes a first wall region, a second wall region and two side regions. The semiconductor structure further includes a dielectric unit having two dielectric liners which are spaced apart from each other in the first direction. The first wall region is located between the two dielectric liners and has an upper surface of the upper wall portion, the second wall region is located beneath the first wall region, and the two side regions extend from an upper surface of the second wall region and are respectively located at two opposite sides of the dielectric unit in the first direction.

In accordance with some embodiments of the present disclosure, each of the two dielectric liners has an upper end which is flush with the upper surface of the upper wall portion, and a lower end which is opposite to the upper end. A level of the lower end is located between a level of an upper surface of the first channel portion and a level of a lower surface of the first channel portion.

In accordance with some embodiments of the present disclosure, a method for manufacturing a semiconductor structure, includes: forming a patterned structure which includes a first protrusion and a second protrusion which are spaced apart from each other, a first channel portion and a second channel portion respectively formed on the first protrusion and the second protrusion, a gate structure which is disposed around the first channel portion and the second channel portion, and two dielectric spacers which are respectively disposed at two opposite sides of the gate structure; performing a preliminary etching process to form an upper trench in an upper portion of the gate structure and an upper portion of each of the two dielectric spacers; performing a main etching process on a lower portion of the gate structure and a lower portion of each of the two dielectric spacers to form a lower trench that extends downwardly from the upper trench, so that the gate structure is formed into a first segment and a second segment which are separated from each other by the upper trench and a first trench region of the lower trench, and each of the two dielectric spacers is formed into a first spacer part and a second spacer part which are separated from each other by the upper trench and a second trench region of the lower trench; performing a selective etching process to widen the first trench region so that a width of the first trench region is greater than a width of the second trench region; and after the selective etching process, forming a dielectric wall in the upper trench and the lower trench.

In accordance with some embodiments of the present disclosure, the first protrusion and the second protrusion are spaced apart from each other in a first direction. The first segment and the second segment are respectively formed around the first channel portion and the second channel portion. The first segment includes a first gate part and a first gate dielectric portion disposed to separate the first gate part from the first channel portion. The second segment includes a second gate part and a second gate dielectric portion disposed to separate the second gate part from the second channel portion. During the selective etching process, the first gate part and the second gate part are etched back in the first direction.

In accordance with some embodiments of the present disclosure, after the selective etching process, the first gate dielectric portion and the second gate dielectric portion are exposed to the lower trench.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming a patterned structure which includes
a first protrusion and a second protrusion which are spaced apart from each other,
a first channel portion and a second channel portion respectively formed on the first protrusion and the second protrusion,
a gate electrode which surrounds the first channel portion and the second channel portion, and
a gate dielectric including a first gate dielectric portion which is disposed to separate the gate electrode from the first channel portion, and a second gate dielectric portion which is disposed to separate the gate electrode from the second channel portion;
performing a first etching process to form an upper trench in an upper portion of the gate electrode;
performing a second etching process on a lower portion of the gate electrode through the upper trench, so that the gate electrode is formed into two gate parts which are separated from each other by the upper trench and a lower trench that extends downwardly from the upper trench, the two gate parts being respectively formed on the first channel portion and the second channel portion;
performing a third etching process on the two gate parts to widen the lower trench; and
after the third etching process, forming a dielectric wall in the upper trench and the lower trench.

2. The method as claimed in claim 1, wherein
the patterned structure further includes a trench isolation which is formed between the first protrusion and the second protrusion, the gate dielectric further including a bottom gate dielectric portion formed on the trench isolation, and
in the second etching process, the lower trench is terminated at the bottom gate dielectric portion.

3. The method as claimed in claim 1, wherein
the patterned structure further includes a trench isolation which is formed between the first protrusion and the second protrusion, the gate dielectric further including a bottom gate dielectric portion formed on the trench isolation, and
in the second etching process, the lower trench is formed to penetrate the bottom gate dielectric portion so as to terminate at the trench isolation.

4. The method as claimed in claim 3, wherein
the first protrusion and the second protrusion are spaced apart from each other in a first direction,
the lower trench has a first trench region formed between the two gate parts and a second trench region formed in the trench isolation, after the third etching process, a maximum width of the first trench region measured in the first direction being greater than a minimum width of the second trench region measured in the first direction.

5. The method as claimed in claim 1, after the first etching process and before the second etching process, further comprising:
forming two dielectric liners respectively on two inner surfaces of the upper trench such that a distance between the two inner surfaces of the upper trench is kept constant from the second etching process to the third etching process.

6. The method as claimed in claim 5, wherein
the first channel portion has an upper surface and a lower surface opposite to the upper surface, and
a bottom of the upper trench formed in the first etching process is located at a level between a level of the upper surface of the first channel portion and a level of the lower surface of the first channel portion.

7. The method as claimed in claim 5, wherein a distance between the two dielectric liners is less than a distance between the first gate dielectric portion and the second gate dielectric portion.

8. The method as claimed in claim 5, wherein
the first protrusion and the second protrusion are spaced apart from each other in a first direction,
during the third etching process, an upper region of each of the two gate parts is protected by a respective one of the two dielectric liners, and a lower region of each of the two gate parts is etched to widen the lower trench, and
after the third etching process, a minimum width of the upper trench measured in the first direction is less than a maximum width of the lower trench measured in the first direction.

9. The method as claimed in claim 1, wherein after the third etching process, the first gate dielectric portion and the second gate dielectric portion are exposed to the lower trench.

10. A method for manufacturing a semiconductor structure, comprising:
forming a patterned structure which includes a first protrusion and a second protrusion which are spaced apart from each other,
a first channel portion and a second channel portion respectively formed on the first protrusion and the second protrusion, and
a gate structure which is disposed around the first channel portion and the second channel portion;
performing a first etching process to form an upper trench in an upper portion of the gate structure;
performing a second etching process on a lower portion of the gate structure, so that the gate structure is formed into a first segment and a second segment which are separated from each other by the upper trench and a lower trench that extends downwardly from the upper trench, the first segment and the second segment being respectively formed around the first channel portion and the second channel portion;
performing a third etching process on the first segment and the second segment so as to widen the lower trench; and
after the third etching process, forming a dielectric wall in the upper trench and the lower trench.

11. The method as claimed in claim 10, further comprising:
forming a dielectric partition in the gate structure such that the second channel portion is located between the dielectric wall and the dielectric partition, a minimum distance from the second channel portion to the dielectric wall being less than a minimum distance from the second channel portion to the dielectric partition.

12. The method as claimed in claim 11, wherein the dielectric partition is formed before the first etching process.

13. The method as claimed in claim 11, wherein the dielectric partition is formed after formation of the dielectric wall, the second segment being disposed between the dielectric partition and the dielectric wall.

14. The method as claimed in claim 10, wherein
the first protrusion and the second protrusion are spaced apart from each other in a first direction,
the patterned structure further includes
a first source/drain portion connected to the first channel portion,
a second source/drain portion connected to the second channel portion, and
an isolation portion which is formed to cover the first source/drain portion and the second source/drain portion and which is located adjacent to the gate structure, and
the upper trench is elongated in a second direction and is formed in an upper portion of the isolation portion, the second direction being transverse to the first direction.

15. The method as claimed in claim 14, wherein in the second etching process, the isolation portion is formed into a first isolation part and a second isolation part which are separated from each other by the upper trench and the lower trench, and which are respectively formed on the first source/drain portion and the second source/drain portion.

16. The method as claimed in claim 15, wherein
the first segment includes a first gate part and a first gate dielectric portion which is disposed to separate the first gate part from the first channel portion,
the second segment includes a second gate part and a second gate dielectric portion which is disposed to separate the second gate part from the second channel portion, and
during the third etching process, the first gate part and the second gate part are etched back at a first etch rate, and the first isolation part and the second isolation part are etched back at a second etch rate that is less than the first etch rate.

17. The method as claimed in claim 16, wherein, after the third etching process, the lower trench has a first width measured in the first direction between the first gate part and the second gate part and a second width measured in the first direction between the first isolation part and the second isolation part, the first width being greater than the second width.

18. A semiconductor structure, comprising:
a first protrusion and a second protrusion spaced apart from each other;
a trench isolation formed between the first protrusion and the second protrusion;
a first channel portion and a second channel portion respectively formed on the first protrusion and the second protrusion;
a first gate part and a second gate part which are respectively formed on the first protrusion and the second protrusion and which are respectively formed around the first channel portion and the second channel portion; and
a dielectric wall including an upper wall portion which is formed between the first gate part and the second gate part, and a lower wall portion which is disposed beneath the upper wall portion and which is formed in the trench isolation, a minimum distance from the upper wall portion to the second channel portion being less than a maximum distance from the lower wall portion to the second protrusion.

19. The semiconductor structure as claimed in claim 18, wherein
the first protrusion and the second protrusion are spaced apart from each other in a first direction,
the upper wall portion includes a first wall region, a second wall region and two side regions,
the semiconductor structure further comprises a dielectric unit having two dielectric liners which are spaced apart from each other in the first direction,
the first wall region is located between the two dielectric liners and has an upper surface of the upper wall portion,
the second wall region is located beneath the first wall region, and
the two side regions extend from an upper surface of the second wall region and are respectively located at two opposite sides of the dielectric unit in the first direction.

20. The semiconductor structure as claimed in claim 19, wherein each of the two dielectric liners has an upper end which is flush with the upper surface of the upper wall portion, and a lower end which is opposite to the upper end, a level of the lower end being located between a level of an upper surface of the first channel portion and a level of a lower surface of the first channel portion.
